(19) United States
(12) Patent Application Publication
(10) Pub. No.: US 2011/0186816 A1
(43) Pub. Date: Aug. 4, 2011

(54) SEMICONDUCTOR DEVICE WAFER, SEMICONDUCTOR DEVICE, DESIGN SYSTEM, MANUFACTURING METHOD AND DESIGN METHOD

(75) Inventors: Tomoyuki Takada, Tsukuba-shi (JP); Masahiko Hata, Tsuchiura-shi (JP); Sadanori Yamanaka, Tsukuba-shi (JP)

(73) Assignee: SUMITOMO CHEMICAL COMPANY, LIMITED, Chuo-ku, Tokyo (JP)

(21) Appl. No.: 13/122,125

(22) PCT Filed: Oct. 1, 2009
(86) PCT No.: PCT/JP2009/005069

§ 371 Date: Mar. 31, 2011

(30) Foreign Application Priority Data
Oct. 2, 2008 (JP) 2008-257858

(51) Int. Cl. H01L 29/165; G06F 17/50; H01L 21/20

(52) U.S. Cl. 257/19; 716/110; 438/478; 257/E29.085; 257/E21.09

(57) ABSTRACT

A device forming thin film for forming a semiconductor device; an inhibition portion that surrounds the device forming thin film and inhibits growth of a precursor of the device forming thin film into a crystal; a sacrificial growth portion that is formed by causing the precursor to sacrificially grow into a crystal, and is positioned around the device forming thin film separated by the inhibition portion; and a protection film that covers a top portion of the sacrificial growth portion and exposes a top portion of the device forming thin film are included. The protection film may be made of polyimide.

### TECHNICAL FIELD

The present invention relates to a semiconductor device wafer, a semiconductor device apparatus, a design system, a manufacturing method, and a design method.

### BACKGROUND ART

Recently, semiconductor devices using a group III-V compound semiconductor such as GaAs as the active region have been developed. For example, Patent Document 1 discloses a semiconductor device wafer in which a GaAs wafer, a buffer layer of AlGaAs, a channel layer of GaAs, and a contact layer of GaAs are arranged in the stated order. In Patent Document 1, the crystal thin film made of compound semiconductor is formed by means of vapor phase epitaxy (VPE).

### [Prior Art Document] [Patent Document]

Patent Document 1: JP11-345812A

### SUMMARY OF THE INVENTION

### Problems to be Solved by the Invention

When using a crystal thin film as an active region of a semiconductor device, it is desirable that the film quality and the film thickness of the thin film is uniform. So as to make the film quality and the film thickness uniform, the deposition environment should be maintained constant at each position of the wafer. Since the growth of a thin film involves various phenomena such as thermal migration in the reaction chamber, the material transfer, the vapor phase reaction, and surface reaction of the sources or the reaction intermediate, which make it difficult to maintain such a constant deposition environment. Particularly in the selective growth by which semiconductors are selectively formed on part of a wafer, the growth rate of the thin film also depends on the size, shape, etc. of the thin film, which makes the manufacturing of a uniform thin film even more difficult. The present invention aims to solve at least one of these problems.

### Means for Solving the Problems

So as to solve the above-mentioned problems, a first embodiment of the present invention provides a semiconductor device wafer including: a device forming thin film for forming a semiconductor device; an inhibition portion that surrounds the device forming thin film and inhibits growth of a precursor of the device forming thin film into a crystal; and a sacrificial growth portion that is formed by causing the precursor to sacrificially grow into a crystal, and is positioned around the device forming thin film separated by the inhibition portion.

The semiconductor device may further include a protection film that covers a top portion of the sacrificial growth portion and exposes a top portion of the device forming thin film. The protection film may be made of polyimide, or may be a multilayer which has a silicon dioxide film and a silicon nitride film stacked to each other. A plurality of sacrificial growth portions around the device forming thin film may also be provided so as to be point symmetric to each other, with respect to the device forming thin film. The device forming thin film and the plurality of sacrificial growth portions each may desirably have the same shape. In this case, the device forming thin film and the plurality of sacrificial growth portions may be positioned at constant intervals in two directions orthogonal to each other on the base wafer.

As a second embodiment of the present invention, the semiconductor device wafer may further include a base wafer made of silicon, where the device forming thin film is a compound semiconductor formed on the silicon of the base wafer by crystal growth. The device forming thin film and the sacrificial growth portion each may include SiₓGe₁₋ₓ (0≦X<1) formed on the silicon of the base wafer by crystal growth and a group III-V compound semiconductor lattice matched or pseudo lattice matched to the SiₓGe₁₋ₓ.

In the semiconductor device wafer, a plane of the silicon on which the device forming thin film may be formed by crystal growth has an off angle tilted from one crystal plane selected from among the (100) plane, the (110) plane, the (111) plane, a plane crystallographically equivalent to the (100) plane, and a plane crystallographically equivalent to the (110) plane, and a plane crystallographically equivalent to the (111) plane. The maximum width of the device forming thin film may be preferably no greater than 50 μm, and further preferably no greater than 30 μm. The maximum width of an outline of the inhibition portion may preferably be no greater than 400 μm.

The semiconductor device wafer is produced by: preparing a semiconductor wafer including a base wafer and an insulating layer that functions as the inhibition portion; determining a size, a shape, and a position of the sacrificial growth portion based on a required specification of the device forming thin film; forming, through the insulating layer, an opening in which the device forming thin film is to be positioned and an opening in which the sacrificial growth portion is to be positioned, the openings exposing the base wafer; and simultaneously forming, by crystal growth, the device forming thin film and the sacrificial growth portion in the opening in which the device forming thin film is to be positioned and in the opening in which the sacrificial growth portion is to be positioned respectively.

A semiconductor device is formed on the device forming thin film, and a semiconductor device capable of being used by a user using a finished semiconductor device product other than the semiconductor device formed on the device forming thin film is not formed in the sacrificial growth portion. Note that a TEG may be formed in the sacrificial growth portion. A semiconductor device apparatus is obtained by dicing the described semiconductor device wafer. In the sacrificially grown crystal, a semiconductor device capable of being used by a user mentioned above is not formed. The sacrificially grown crystal may be a single crystal or a polycrystal.

### BRIEF DESCRIPTION OF THE DRAWINGS

FIG. 1 is a plan view of a semiconductor device wafer 100.

FIG. 2 is a plan view of the semiconductor device wafer 100.

FIG. 3 is a plan view of the semiconductor device wafer 100 and semiconductor apparatuses 460.

FIG. 4 is a flowchart showing a design method of the semiconductor device wafer 100.

FIG. 5 is a process chart showing a process of manufacturing the semiconductor device wafer 100 and the semiconductor apparatus 460.

FIG. 6 is a block diagram showing an example of the wafer design system 600.

FIG. 7 is a graph showing an exemplary mutual relation between the film thickness of a thin film and the size of the inhibition portion 114.

FIG. 8 is a graph showing an exemplary mutual relation between the film thickness of the thin film and the size of the inhibition portion 114.

FIG. 9 shows a plan view of a semiconductor device wafer 3000 formed in Embodiment Example 2.

FIG. 10 is a graph showing a relation between the growth rate of a device forming thin film 3004 and a width of the inhibition portion 3002.

FIG. 11 is a graph showing a relation between the growth rate and the area ratio of the device forming thin film 3004.

FIG. 12 is a graph showing a relation between the growth rate of the device forming thin film 3004 and the width of the inhibition portion 3002.

FIG. 13 is a graph showing a relation between the growth rate and the area ratio of the device forming thin film 3004.

FIG. 14 is a graph showing a relation between the growth rate of the device forming thin film 3004 and the width of the inhibition portion 3002.

FIG. 15 is a graph showing a relation between the growth rate and the area ratio of the device forming thin film 3004.

FIG. 16 is an electron micrograph of the surface of the semiconductor device wafer 3000 when the off angle of the base wafer is set to be 2 degrees.

FIG. 17 is an electron micrograph of the surface of the semiconductor device wafer 3000 when the off angle of the base wafer is set to be 2 degrees.

FIG. 18 is an electron micrograph of the surface of the semiconductor device wafer 3000 when the off angle of the base wafer is set to be 6 degrees.

FIG. 19 is an electron micrograph of the surface of the semiconductor device wafer 3000 when the off angle of the base wafer is set to be 6 degrees.

FIG. 20 is a plan view of a heterojunction bipolar transistor (HBT) 3100.

FIG. 21 is an electron micrograph of a portion of FIG. 20 surrounded by a dashed line.

FIG. 22 is an enlarged plan view of the three HBT elements 3150 in FIG. 21 surrounded by a dashed line.

FIG. 23 is a laser electron micrograph of the region of the HBT element 3150.

FIG. 24 is a plan view of the HBT 3100 in one of the sequential manufacturing steps.

FIG. 25 is a plan view of the HBT 3100 in one of the sequential manufacturing steps.

FIG. 26 is a plan view of the HBT 3100 in one of the sequential manufacturing steps.

FIG. 27 is a plan view of the HBT 3100 in one of the sequential manufacturing steps.

FIG. 28 is a plan view of the HBT 3100 in one of the sequential manufacturing steps.

FIG. 29 is a graph showing the measurement data of one of various characteristics of the manufactured HBT 3100.

FIG. 30 is a graph showing the measurement data of one of the various characteristics of the manufactured HBT 3100.

FIG. 31 is a graph showing the measurement data of one of the various characteristics of the manufactured HBT 3100.

FIG. 32 is a graph showing the measurement data of one of the various characteristics of the manufactured HBT 3100.

FIG. 33 is a graph showing the measurement data of one of the various characteristics of the manufactured HBT 3100.

FIG. 34 is the measurement data of the depth profile by the secondary ion mass spectroscopy.

FIG. 35 is a TEM photograph showing a sectional view of the HBT formed simultaneously with the HBT 3100.

FIG. 36 shows an HBT including a device forming thin film on a plain wafer that does not include an inhibition portion.

### MODE FOR CARRYING OUT THE INVENTION

Some aspects of the invention will now be described based on the embodiments, which do not intend to limit the scope of the present invention, but exemplify the invention. All of the features and the combinations thereof described in the embodiment are not necessarily essential to the invention.

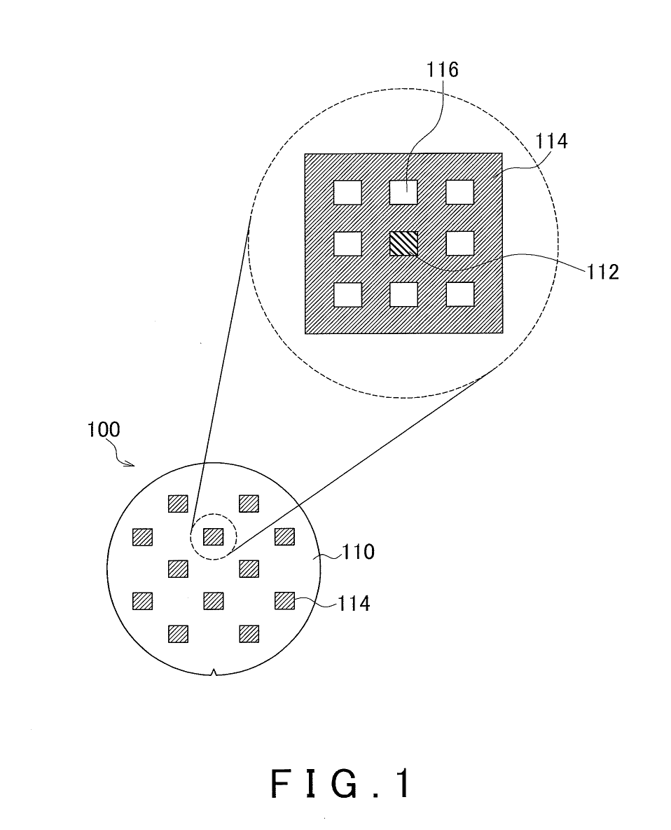

FIG. 1 is a plan view of a semiconductor device wafer 100. The semiconductor device wafer 100 includes a base wafer 110, a device forming thin film 112 for forming a semiconductor device, an inhibition portion 114 for inhibiting the precursor of the device forming thin film 112 from growing into a crystal, and sacrificial growth portions 116 resulting from sacrificial growth of the precursor into crystals. The base wafer 110 of the present embodiment is a Si wafer. The other examples of the base wafer 110 includes an SOI (Silicon on Insulator) wafer, a Ge wafer, a GOI (Germanium on Insulator) wafer, a GaAs wafer, an InP wafer, a glass wafer, a sapphire wafer, a ceramic wafer, and a plastic wafer.

The device forming thin film 112 is formed, by crystal growth, on the base wafer 110 inside the opening formed through the inhibition portion 114. Therefore, the device forming thin film 112 is surrounded by the inhibition portion 114. The center of the device forming thin film 112 substantially matches the center of the inhibition portion 114. The device forming thin film 112 is a compound semiconductor used for forming a semiconductor device. The device forming thin film 112 is shaped as a square in a plan view in the present embodiment, and may also be shaped as a rectangle, a polygon, a round, or an ellipse in the plan view.

The device forming thin film 112 may be SiₓGe₁₋ₓ (0≦X<1), or a group III-V compound semiconductor such as GaAs, AlGaAs, or InGaP, formed by chemical vapor deposition (occasionally referred to as “CVD”). Various dopants are doped in the device forming thin film 112, thereby forming a plurality of thin films such as a buffer layer, an active layer, or a contact layer of a semiconductor device. Accordingly, the device forming thin film 112 constitutes a part of a semiconductor device. The device forming thin film 112 may have been annealed.

The device forming thin film 112 may include a seed layer of SiₓGe₁₋ₓ (0≦X<1) in contact with the base wafer 110. The seed layer is formed by an epitaxial growth method. The device forming thin film 112 is formed by overlapping a plurality of SiₓGe₁₋ₓ layers (0≦X<1). The composition of the plurality of SiₓGe₁₋ₓ layers may be such that x approaches 1 as closer to the base wafer 110. In contact with the seed layer, an InGaP buffer layer may be formed by an epitaxial growth method. In contact with the InGaP buffer layer, a GaAs active layer may be formed by epitaxial growth method. In contact with the GaAs, a GaAs contact layer is formed by epitaxial growth method.

The film thickness of the device forming thin film 112 is, for example, 5 nm to 15 μm. In the present application, the terms such as “film thickness” and “layer thickness” represents the average thickness of a thin film and a layer respectively. The average thickness can be determined by measuring the film thickness at two or more points in a sectional view of a crystal observed through a transmission electron microscope and a scanning electron microscope, and averaging the measured values.

Examples of semiconductor devices formed on the device forming thin film 112 include active elements such as a MOS transistor, a heterojunction bipolar transistor (HBT), a high electron mobility transistor (HEMT), a semiconductor laser, a light emitting diode, a light emitting thyristor, a light receiving diode, and a solar cell, and passive elements such as a resistor, a capacitor, and an inductor.

On the surface of the inhibition portion 114, the precipitation of the thin layer attributed to the precursor of the device forming thin film 112 is restrained. Accordingly, the crystal growth of the device forming thin film 112 is inhibited in the region in which the inhibition portion 114 has been formed. The inhibition portion 114 may be an insulating layer of SiO₂ formed on a main plane of the base wafer 110 for example, and inhibits crystal growth of the precursor of the device forming thin film 112 either SiₓGe₁₋ₓ (0≦X<1) or a group III-V compound semiconductor. Another example of the inhibition portion 114 is a nitride film such as Si₃N₄, TaN, and Ti₃N₄.

In the present embodiment, each inhibition portion 114 is shaped as a rectangle, and a plurality of inhibition portions 114 are arranged in the main plane of the base wafer 110 at a constant interval between each other. The base wafer 110 may be a Si wafer. The inhibition portion 114 is an insulating layer of SiO₂, which is shaped as a square in a plan view and having the layer thickness of 0.05 to 5 μm. In each inhibition portion 114, one device forming thin film 112 and eight sacrificial growth portions 116 are formed.

The sacrificial growth portions 116 function to stabilize the crystal growth of the device forming thin film 112 by causing the precursor of the device forming thin film 112 to sacrificially grow. This helps stabilize the film quality and the film thickness of the device forming thin film 112. Here, the term “sacrificial growth” means crystal growth of a precursor of a semiconductor device, without intending to form a device capable of being used by a user using a finished product of a semiconductor device formed in the device forming thin film 112 other than the semiconductor device. Each sacrificial growth portion 116 may be a single crystal having the same quality as the device forming thin film 112, or a crystal having a lower quality in terms of including more lattice defects than the device forming thin film 112. Each sacrificial growth portion 116 may also be a polycrystal.

The sacrificial growth portions 116 are formed on the base wafer 110 where the inhibition portion 114 is not formed. More specifically, the sacrificial growth portions 116 are formed in respective openings of the inhibition portion 114 in the vicinity of the device forming thin film 112. By doing so, the sacrificial growth portions 116 are formed around the device forming thin film 112 separated by the inhibition portion 114. Although shown as a rectangle in the plan view of in FIG. 1, each sacrificial growth portion 116 may have a shape of a polygon other than the rectangle, a round, an ellipse, or an oval in the plan view.

The plurality of sacrificial growth portions 116 are formed around the device forming thin film 112 to surround the device forming thin film 112. The plurality of sacrificial growth portions 116 are provided so as to be point symmetric to each other, with respect to the device forming thin film 112. Although drawn in FIG. 1 to have the same size and the same planar shape as the device forming thin film 112, the sacrificial growth portions 116 may have band-like shapes in another example.

When the device forming thin film 112 and the sacrificial growth portions 116 each have the same shape, it is further preferable that they are provided in constant intervals between them, in two orthogonal directions on the base wafer 110. An example of such a formation is shown in FIG. 1, in which the three rows of openings are parallel to one side of the inhibition portion 114 having a rectangular outline, and three columns of openings are parallel to another side of the inhibition portion 114. The device forming thin film 112 or the sacrificial growth portions 116 are formed in the openings arranged in three rows by three columns, in constant intervals between them.

The device forming thin film 112 and the sacrificial growth portions 116 each include SiₓGe₁₋ₓ (0≦X<1) formed on the silicon of the base wafer 110 by crustal growth, and a group III-V compound semiconductor lattice matched or pseudo lattice matched to the SiₓGe₁₋ₓ.

Examples of the semiconductor device formed on the device forming thin film 112 include a MOSFET (Metal Oxide Semiconductor Field Effect Transistor), a HEMT (High Electron Mobility Transistor), a pseudomorphic HEMT, and a MESFET (Metal Semiconductor Field Effect Transistor).

As opposed to this, a semiconductor device capable of being used by a user using a finished semiconductor device product other than the semiconductor device formed on the device forming thin film is not formed in the sacrificial growth portions 116. The sacrificial growth portions 116 can be used as an examination region for examining the crystallinity of the device forming thin film 112. A TEG (Test Element Group) or an evaluation element may be formed in the sacrificial growth portions 116. The evaluation element is used when the characteristics of the device forming thin film 112, or the effect that the device forming thin film 112 has on the electrical characteristics of a semiconductor device are examined. The TEG or the evaluation element may be a passive element or an active element.

A semiconductor device apparatus can be formed by dicing the semiconductor device wafer 100 having the device forming thin film 112 and the sacrificial growth portions 116.

The semiconductor device wafer 100 may include a protection film that covers a top portion of the sacrificial growth portions 116, but exposes a top portion of the device forming thin film 112. The protection film is an insulating film including polyimide, a silicon oxide film, a silicon nitride film, or a layered composite of them. The protection film may be formed by stacking polyimide on the layered composite of the silicon oxide film and the silicon nitride film. The layered composite of the silicon oxide film and the silicon nitride film is formed by, for example, ion beam sputtering. The application of polyimide can be pursued by spin coating, for example.

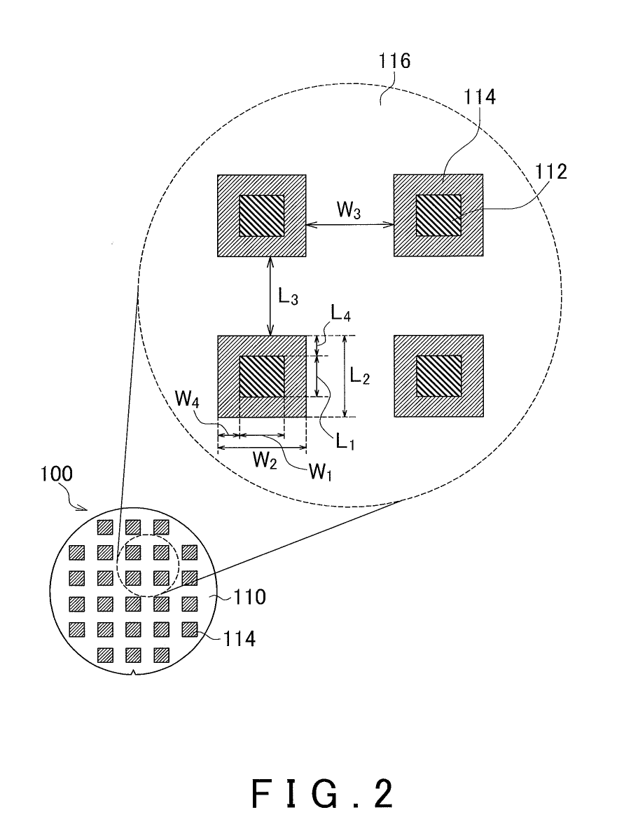

FIG. 2 is another exemplary plan view of the semiconductor device wafer 100. The semiconductor device wafer 100 in FIG. 2 has the same basic configuration as the semiconductor device wafer 100 shown in FIG. 1, and so is explained as follows focusing on its difference from the semiconductor device wafer 100 in FIG. 1. In FIG. 2, the sacrificial growth portion 116 is not formed in the inhibition portion 114.

A plurality of inhibition portions 114 are provided at a constant interval between each other, on a main plane of the base wafer 110. Each inhibition portion 114 is an insulating layer of SiO₂ shaped as a square in a plan view and having the layer thickness of 1 μm. Inside each one of the inhibition portions 114, one device forming thin film 112 shaped as a square in a plan view is formed. In the present embodiment, the device forming thin films 112 are arranged at the center of the inhibition portions 114 respectively, and a sacrificial growth portion 116 is provided in a region in which no inhibition portion 114 is formed on the base wafer 110.

During designing of the semiconductor device wafer 100, the length L₂ of an inhibition portion 114, the width W₂ of an inhibition portion 114, the distances L₃ and W₃ between two adjacent inhibition portions 114 are determined based on the length L₁ or the width W₁ of the device forming thin film 112, the composition and the film thickness of the thin film formed on the device forming thin film 112. The intervals L₄ and W₄ between a device forming thin film 112 and the corresponding inhibition portion 114 are also determined in the same manner. In the present embodiment, determining the sizes L₂ and W₂ of the inhibition portion 114 allows to determine the size and the shape of the sacrificial growth portion 116.

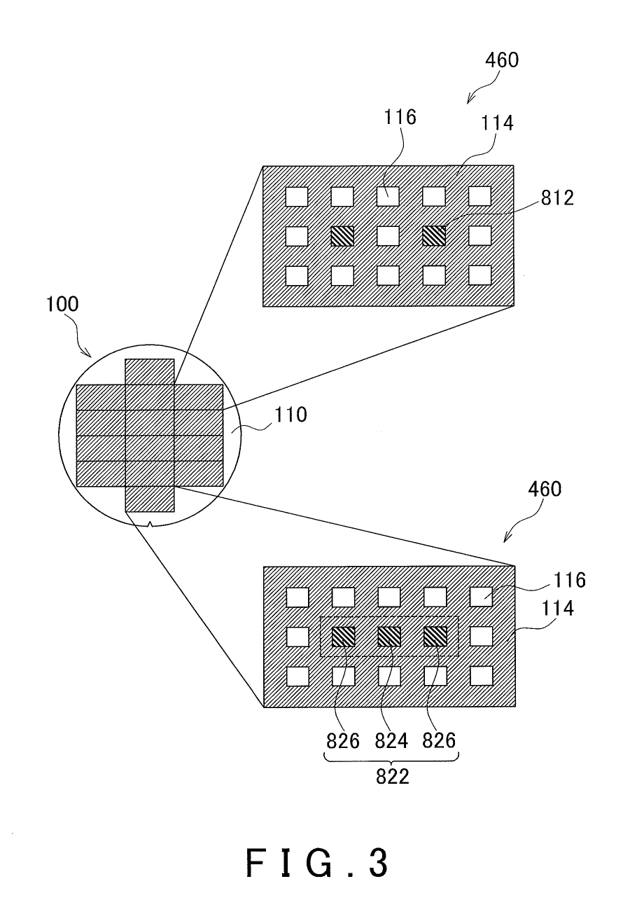

FIG. 3 is a plan view of the semiconductor device wafer 100 and a semiconductor apparatus 460 formed on the semiconductor device wafer 100. The semiconductor device wafer 100 in FIG. 3 has the same basic configuration as the semiconductor device wafer 100 shown in FIG. 1, and so is explained as follows focusing on its difference from the semiconductor device wafer 100 in FIG. 1.

The semiconductor device wafer 100 includes a plurality of semiconductor apparatuses 460 manufactured on the base wafer 110. In each of the semiconductor apparatuses 460, one inhibition portion 114 is formed. In one inhibition portion 114, a plurality of device forming thin films 812 or a plurality of device forming thin films 822, and a plurality of sacrificial growth portions 116 surrounding the device forming thin films 812 or the device forming thin films 822 are formed.

A semiconductor layer is formed in the device forming thin films 812, 822, and the semiconductor layer is used for forming a semiconductor device. The device forming thin films 822 are classified into the core region 824 and the sub regions 826. The core region 824 is nearer the center of the inhibition portion 114 than the sub regions 826. For this reason, the film quality of the core region 824 is more uniform than the film quality of the sub regions 826. The core region 824 is used as an active region of an active element, and passive elements are formed on the sub regions 826.

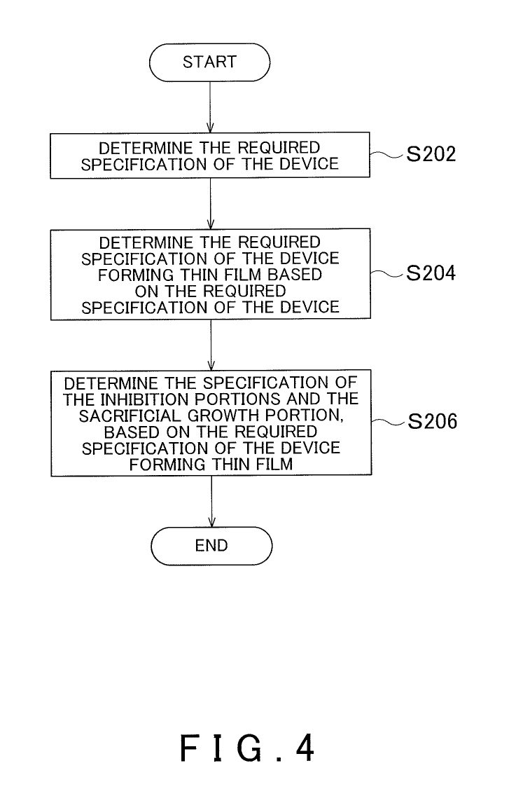

FIG. 4 is a flowchart showing an exemplary design method of the semiconductor device wafer 100 shown in FIG. 1 through FIG. 3. First, the required specification of the semiconductor device is determined (S202). The required specification of the semiconductor device may be the type, the structure, and the position of the semiconductor device, for example. The example of the type of the semiconductor device includes an active element such as a transistor, and a passive element such as a resistor or a capacitor. When the semiconductor device is, for example, a transistor, the structure of the semiconductor device is a MOS transistor, HBT, HEMT, etc. Another example of the required specification of the semiconductor device is the type of the base wafer 110, or the specification of the active layer. The specification of the active layer may be the position, the layer thickness, the composition of the active layer, and the type of the dopant, the doping amount, the resistivity, and the withstanding voltage, for example.

Next, the required specification of the device forming thin film 112 is determined based on the required specification of the semiconductor device (S204). The required specification of the device forming thin film 112 is the size, the shape, the position, the resistivity, or the withstanding voltage of the device forming thin film 112. Here, the size may include the area, the volume, the height, the depth, and the thickness, in addition to the length and the width. The size and the position of the device forming thin film 112 are determined based on the size, the number, and the position of the active region of the semiconductor device, for example. The required specification of the device forming thin film 112 may further include the structure, the composition, the dopant, the doping amount, the film thickness, and the growth rate of the thin film. More specifically, the required specification of the device forming thin film 112 may also include the structure, the composition, the dopant, the doping amount, and the film thickness of a thin film layer used as an active region, a buffer layer positioned between the thin film layer and the base wafer 110, or the like.

The design specification of the inhibition portion 114 and the sacrificial growth portion 116 is determined based on the required specification of the device forming thin film 112 (S206). The design specification of the inhibition portion 114 and the sacrificial growth portion 116 includes the size, the shape, the position, the material, and the thickness of the inhibition portion 114 and the sacrificial growth portion 116. The mutual relation between the required specification of the device forming thin film 112 and the design specification of the inhibition portion 114 and the sacrificial growth portion 116 may be pre-stored in the design system of the semiconductor device wafer, so that the design specification of the inhibition portion 114 may be determined based on the required specification of the device forming thin film 112, by referring to the stored mutual relation. The mutual relation may include the area ratio or the positional relation for the device forming thin film 112, the inhibition portions 114, and the sacrificial growth portion(s) 116. The mutual relation may include the area ratio or the positional relation for each type and film thickness of the device forming thin film 112.

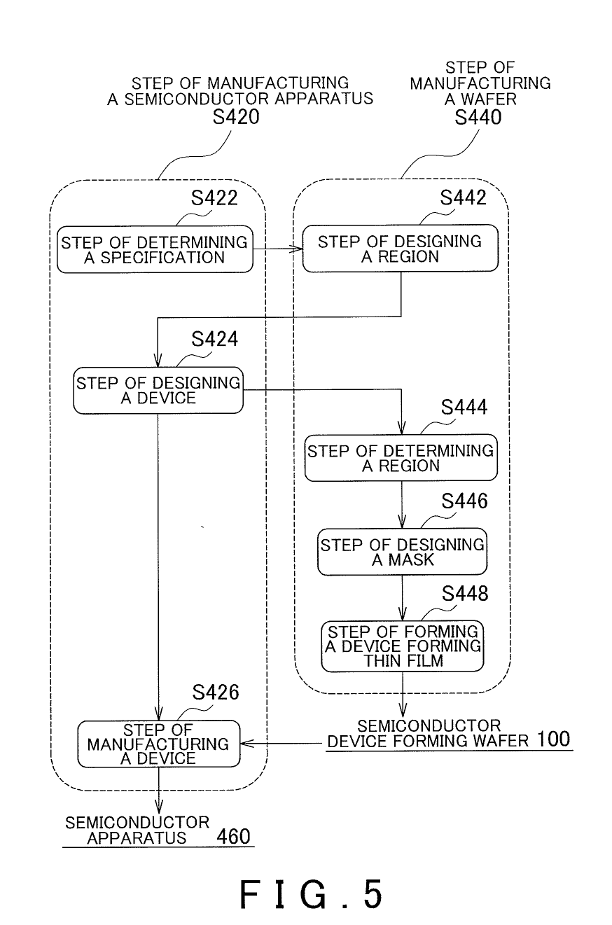

FIG. 5 shows an exemplary process of manufacturing the semiconductor device wafer 100 and the semiconductor apparatuses 460. The semiconductor device wafer 100 is manufactured in Step S440 of manufacturing a wafer, and the semiconductor apparatus 460 is manufactured in Step S420 of manufacturing the semiconductor apparatus and Step S440 of manufacturing the wafer. Step S420 of manufacturing the semiconductor apparatus includes Step S422 of determining a specification, Step S424 of designing a device, and Step S426 of manufacturing a device. Step S440 of manufacturing a wafer includes Step S442 of designing a region, Step S444 of determining a region, Step S446 of designing a mask, and Step S448 of forming a thin film.

In Step S422 of determining a specification, the requested specification of a device to be formed on the device forming thin film 112 is determined first. For example, the size, the shape, and the position of the active region of the semiconductor device, as well as the composition and the film thickness of the device forming thin film 112 used as the active region are determined. Next, the required specification of the device forming thin film 112 is determined based on the required specification of the semiconductor device.

In Step S442 of designing a region, a candidate of the design specification of the inhibition portion 114 and the sacrificial growth portion 116 is calculated based on the required specification of the device forming thin film 112. For example, the length L₂ and the width W₂ of an inhibition portion 114, the intervals L₃ and W₃ between two adjacent inhibition portions 114, as well as the intervals L₄ and W₄ between the device forming thin film 112 and an inhibition portion 114 are determined. The thickness of the inhibition portion 114 may also be determined.

The required specification of the device forming thin film 112 and the candidate of the design specification of the inhibition portion 114 and the sacrificial growth portion 116 may be determined as a single value, or as a range. When the required specification and the design specification are determined as a single value, they are calculated so that the center of the device forming thin film 112 matches the center of the active region of the semiconductor device. On the other hand, when the design specification is determined as a range, the allowable range of the sizes L₂ and W₂ for the inhibition portion 114 may be calculated for example. When either the required specification or the design specification is determined as a range, the calculation may be performed so that the size of the device forming thin film 112 or the thickness of the inhibition portion 114 be selectable depending on the maximum temperature allowed on the design.

The sacrificial growth portion 116 may be formed inside the inhibition portion 114. In this case, the range of the area of the sacrificial growth portions 116 formed on the side on which the source gas is supplied with reference to the device forming thin film 112 may be different in size from the range of the area of the sacrificial growth portions 116 formed on the side opposite to the supply side of the source gas. In addition, the thickness of the inhibition portion may be calculated that would cause the height of the sacrificial growth portion 116 to be substantially the same as height of the device forming thin film 112.

In Step S424 of designing a device, a semiconductor device is designed based on the required specification of the device forming thin film 112, and the candidate of the design specification of the inhibition portion 114 and the sacrificial growth portion 116 determined in Step S442 of designing a region. Depending on the required specification of the device forming thin film 112 and the design specification of the inhibition portion 114 and the sacrificial growth portion 116 determined so far, the required specification of the semiconductor device may be changed, and then Step 422 of determining a specification, Step S442 of designing a region, and Step S424 of designing a device may be repeated again.

In Step S444 of determining a region, the design specification of the device forming thin film 112, the inhibition portion 114, and the sacrificial growth portion 116 are determined, based on the required specification of the device forming thin film 112, and the candidate of the design specification of the inhibition portion 114 and the sacrificial growth portion 116 designed in Step S424 of designing a device. The film thickness and the film quality of the device forming thin film 112 may be made uniform by incorporating the inhibition portions 114 and the sacrificial growth portion(s) 116 in the semiconductor device wafer 100. By having the common design specification for the inhibition portions 114 and the sacrificial growth portion(s) 116, in both of Step S420 of manufacturing a semiconductor apparatus and Step S440 of manufacturing a wafer, the semiconductor device wafer 100 and the semiconductor apparatuses 460 can be efficiently designed.

In Step S446 of designing a mask, a mask to be used in patterning the inhibition portions 114 is designed based on the required specification of the device forming thin film 112 and the design specification of the inhibition portion 114 and the sacrificial growth portion 116 determined in Step S444 of determining a region. More specifically, the mask is designed based on the size, the shape, and the position of the inhibition portion 114 and the sacrificial growth portion 116 included in the design specification of the inhibition portion 114 and the sacrificial growth portion 116, and the required specification of the device forming thin film 112.

In Step S448 of forming a thin film, a base wafer 110 including silicon and an insulating layer covering at least a part of the silicon is prepared. The insulating layer has SiO₂ on its surface, to inhibit crystal growth of the device forming thin film 112.

Next, the insulating layer is patterned by photolithography, etching, or the like, using the mask designed in Step S446 of designing a mask. Accordingly, the inhibition portions 114 is formed, which has an opening in which the device forming thin film 112 is to be provided and openings in which the sacrificial growth portions 116 are to be provided are formed. The openings are formed in a substantially perpendicular direction to the semiconductor device wafer 100, and reach the base wafer 110. Here, the concept “substantially a perpendicular direction” includes a direction slightly tilted from the perpendicular direction, in consideration of the manufacturing error of the wafer and each member, not only the strict perpendicular direction.

The patterning may divide the insulating layer to obtain a plurality of divisions at constant intervals between each other. In this case, each division of the insulating layer functions as an inhibition portion 114. Each inhibition portion 114 may be a rectangle, a polygon, a round, or an ellipse, or an oval. A precursor of the device forming thin film 112 can be sacrificially grown into a crystal, in the region from which the insulating layer is removed.

In Step S448 of forming a thin film, under the condition where the reaction of the precursor of the device forming thin film 112 is the rate-controlling factor, or under the condition where the supply of the precursor is the rate-controlling factor, the device forming thin film 112 and the sacrificial growth portions 116 are selectively epitaxially grown simultaneously inside the plurality of openings. The device forming thin film 112 is formed by CVD. PVD may also be used in another example. Accordingly, the device forming thin film 112 and the sacrificial growth portions 116 are grown from the silicon of the base wafer 110 exposed in the opening, the silicon serving as a growth nucleus. The device forming thin film 112 may include SiₓGe₁₋ₓ (0≦X<1), and further a group III-V compound semiconductor grown from SiₓGe₁₋ₓ (0≦X<1) serving as a growth nucleus.

A buffer layer of InGaP, or a separation layer obtained by oxidizing the group III-V compound semiconductor including Al may be provided between SiₓGe₁₋ₓ and the group III-V compound semiconductor. The separation layer may be made of a material capable of electrically separating SiₓGe₁₋ₓ from the group III-V compound semiconductor as well as having a lattice constant that is close to the lattice constant of SiₓGe₁₋ₓ and the group III-V compound semiconductor. The group III-V compound semiconductor is formed under the condition under which supply of the precursor of the group III-V compound semiconductor is the rate-controlling factor, for example.

The crystal growth by CVD is pursued by (a) transport of source molecules to the wafer surface, (b) chemical reaction on the wafer surface or in the vicinity thereof, (c) generation of a crystal nucleus and crystal growth of a thin film, and (d) removal of the reaction bi-product. In other words, the source gas supplied in the reaction apparatus generates a precursor being a reaction intermediate by vapor phase reaction. The generated precursor is diffused in the vapor phase to be adsorbed on the wafer surface. The precursor adsorbed on the wafer surface is precipitated as a solid film after surface diffusion on the wafer surface.

The deposition rate in CVD is determined by a combination of the rate of the physical processes (a) through (d) and the rate of the chemical process. For example, when the reaction rate of the process (b) is sufficiently faster than the transport rate of the sources in the process (a), the deposition rate is proportional to the amount of the transported sources, and does not largely depend on the growth temperature. Such a situation is called as “supply-limited,” or “diffusion-limited.” On the other hand, when the reaction rate of the process (b) is slower than the transport rate of the sources in the process (a), the deposition rate largely depends on the growth temperature. Such a situation is called as “reaction-limited.”

In the case of “supply-limited,” or “diffusion-limited,” the rate at which the precursor is supplied to the device forming thin film 112 can be controlled by controlling the rate at which the sources are supplied. In the case of “reaction-limited,” on the other hand, the rate at which the precursor is supplied to the device forming thin film 112 can be controlled by controlling the growth temperature or the concentration ratio of the source gas including the carrier gas. By controlling the rate at which the precursor is supplied, the growth rate and the film quality of the device forming thin film 112 can be controlled.

After crystal growth of the device forming thin film 112 and the sacrificial growth portions 116, the sacrificial growth portions 116 may be scraped off. For example, the sacrificial growth portions 116 may be scraped off by etching. After scraping off the sacrificial growth portions 116, another semiconductor device capable of being used by a user using a finished product of the semiconductor device formed in the device forming thin film 112 may be formed in the regions that used to be provided with the sacrificial growth portions 116. When the sacrificial growth portions 116 remain without being scraped off, a device for testing the semiconductor device formed on the device forming thin film 112 may be formed on the mentioned regions.

After forming the device forming thin film 112 and the sacrificial growth portions 116 by crystal growth, the sacrificial growth portions 116 may be covered by a protection film. The protection film is an insulating film including polyimide, a silicon oxide film, a silicon nitride film, or a layered composite of them.

Note that not limited to a Si wafer, a Ge wafer or a GOI wafer may also be used as the base wafer 110. The Ge wafer or the GOI wafer may include Si_{Y}Ge_{1-Y} (0≦Y<1). Here, the semiconductor layer formed on the device forming thin film 112 and the sacrificial growth portions 116 may include a group III-V compound semiconductor having been grown by using, as a growth nucleus, Si_{Y}Ge_{1-Y} of the base wafer 110 exposed in the opening in which the device forming thin film 112 is to be provided. The buffer layer of InGaP or the separation layer may be positioned between Si_{Y}Ge_{1-Y} and the group III-V compound semiconductor.

In Step S426 of manufacturing a device, a semiconductor apparatus is manufactured by forming a semiconductor device on the semiconductor device wafer 100 manufactured in Step S440 of manufacturing a wafer, based on the design of the semiconductor device designed in Step S424 of designing a device. The semiconductor device is formed on the device forming thin film 112 through various semiconductor manufacturing processes.

Each step shown in FIG. 5 may be realized by hardware, or a combination of hardware and software controlling the hardware. In other words, the above description discloses a semiconductor apparatus manufacturing system which includes a semiconductor apparatus manufacturing section and a wafer manufacturing section. The semiconductor apparatus manufacturing section performs Step S420 of manufacturing a semiconductor apparatus. The wafer manufacturing section performs Step S440 of manufacturing a wafer.

The semiconductor apparatus manufacturing section includes a specification determining section, a device designing section, and a device manufacturing section. The specification determining section, the device designing section, and the device manufacturing section perform Step S422 of determining a specification, Step S424 of designing a device, and Step S426 of manufacturing a device, respectively.

The wafer manufacturing section includes a region designing section, a region determining section, a mask designing section, and a thin film forming section. The region designing section, the region determining section, the mask designing section, and the thin film forming section perform Step S442 of determining a region, Step S444 of determining a region, Step S446 of designing a mask, and Step S448 of forming a thin film, respectively.

The semiconductor manufacturing section and the wafer manufacturing section are connected to each other by a wired or wireless network, and information outputted from the semiconductor manufacturing section may be received by the wafer manufacturing section. Also, information outputted from the wafer manufacturing section may be received by the semiconductor manufacturing section.

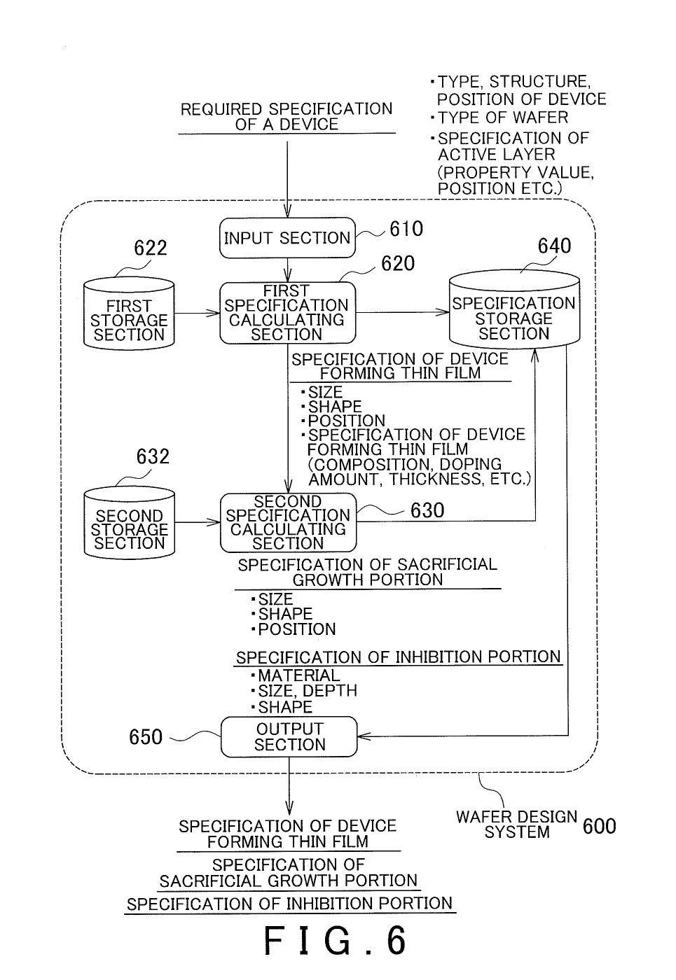

FIG. 6 shows a wafer design system 600 used for designing the semiconductor device wafer 100. The wafer design system 600 includes an input section 610, a first storage section 622, a second storage section 632, a first specification calculating section 620, a second specification calculating section 630, a specification storage section 640, and an output section 650. The wafer design system 600 designs the semiconductor device wafer 100 in Step S442 of designing a region shown in FIG. 5. In response to receiving the required specification of the semiconductor device, the wafer design system 600 outputs the required specification of the device forming thin film 112 and the design specification of the inhibition portion 114 and the sacrificial growth portion 116.

The required specification of the semiconductor device is inputted to the input section 610. The input section 610 may include an input apparatus such as a keyboard and a mouse. The input section 610 may include a communication interface and a network communication apparatus, to receive the data via a telecommunications line such as a dedicated communication network and the Internet. Examples of the required specification of the semiconductor device inputted to the input section 610 include the type of the base wafer 110 and the specification of the active layer of the active element formed on the device forming thin film 112. The specification of the active layer may be the position, the layer thickness, the composition of the active layer, the type of the dopant, the doping amount, the resistivity, and the withstand voltage, for example.

The first storage section 622 stores the mutual relation between the composition, the size, the shape, and the position of the active layer, and the size, the shape, and the position of the device forming thin film 112 which is an example of the required specification of the device forming thin film 112. The mentioned mutual relation may be a mutual relation between characteristics such as mobility or resistivity of the active layer, and the composition, the film thickness, and the doping amount of the device forming thin film 112. The first storage section 622 stores the mutual relation in a table format. The first specification calculating section 620 calculates the required specification of the device forming thin film 112 based on the mutual relation stored in the first storage section 622 and the required specification of the semiconductor device inputted to the input section 610. Thus calculated required specification is stored in the specification storage section 640.

When the device forming thin film 112 is not heated to about 600 to 900 degrees centigrade, it is desirable to calculate the size of the device forming thin film 112 at which the aspect ratio of the device forming thin film 112 is no smaller than (\sqrt{3})/3 (equal to about 0.577). More specifically, when the plane orientation of a main plane of the base wafer 110 is (100), it is desirable that the aspect ratio of the device forming thin film 112 is no smaller than 1. When the plane orientation is (111), it is desirable that the aspect ratio is no smaller than \sqrt{2} (equal to about 1.414). When the plane orientation is (110), it is desirable that the aspect ratio is no smaller than (\sqrt{3})/3 (equal to about 0.577). Here, the aspect ratio of the device forming thin film 112 is obtained by dividing “film thickness of the device forming thin film 112” by “the smaller of the length L₁ or the width W₁ of the device forming thin film 112.”

On the other hand, when the device forming thin film 112 can be heated to about 600 through 900 degrees centigrade, the size of the device forming thin film 112 may be calculated at which the aspect ratio of the device forming thin film 112 is smaller than \sqrt{2} (equal to about 1.414). More specifically, when the plane orientation of a main plane of the base wafer 110 is (100), the aspect ratio of the device forming thin film 112 may be smaller than 1. When the plane orientation is (111), the aspect ratio may be \sqrt{2} (equal to about 1.414). When the plane orientation is (110), the aspect ratio may be smaller than (\sqrt{3})/3 (equal to about 0.577).

The second specification calculating section 630 calculates the design specification of the inhibition portion 114 and the sacrificial growth portion 116, based on the required specification of the device forming thin film 112 calculated by the first specification calculating section 620.

On the surface of the inhibition portion 114, the precipitation of the precursor of the device forming thin film 112 is inhibited. Accordingly, the precursor once adsorbed onto the surface of an inhibition portion 114 is diffused on the surface of the inhibition portion 114. A part of the precursor diffused on the inhibition portion 114 reaches the device forming thin film 112, to precipitate inside the device forming thin film 112 as a solid film. Another part of the precursor reaches the sacrificial growth portion 116, to precipitate as a solid film inside the sacrificial growth portion 116. A further different portion of the precursor is diffused outside the inhibition portion 114, to precipitate as a solid film on the region in which no inhibition portion 114 is formed. When the size of the device forming thin film 112 is sufficiently smaller than the size of the inhibition portion 114, most of the precursor supplied to the device forming thin film 112 is supplied by diffusion on the surface of the inhibition portion 114.

As the ratio of the area of the device forming thin film 112 with respect to the inhibition portion 114 gets smaller, the amount of precursor supplied in the unit area of the device forming thin film 112 increases, to increase the deposition rate. Likewise, as the ratio of the area of the sacrificial growth portion 116 with respect to the inhibition portion 114 gets larger, the amount of precursor that can reach the device forming thin film 112 decreases, to decrease the deposition rate. Furthermore, as the distance from the periphery of the device forming thin film 112 to the sacrificial growth portion 116 becomes longer, the amount of precursor supplied to the device forming thin film 112 increases, to increase the deposition rate. Therefore, the growth rate of the device forming thin film 112 may be set as the required specification, and the area ratio of the inhibition portion 114 with respect to the device forming thin film 112 and the sacrificial growth portion 116 and the distance from the periphery of the device forming thin film 112 to the sacrificial growth portion 116 may be set as the design specification, and the mutual relation between thus set required specification and design specification may be pre-stored in the second storage section 632.

When the deposition rate is too fast, the film quality becomes instable. Therefore, the required specification of the device forming thin film 112 and the design specification of the inhibition portion 114 and the sacrificial growth portion 116 are determined by taking into consideration the balance between the deposition rate and the film quality. The position of the sacrificial growth portion 116 relative to the device forming thin film 112 may also be calculated by taking into consideration the flow condition of the source gas.

The specification of the inhibition portion 114 and the sacrificial growth portion 116 calculated by the second specification calculating section 630 is transmitted to the specification storage section 640, and stored in the specification storage section 640. The second specification calculating section 630 may calculate the material, the thickness, the size, the shape, and the position of the inhibition portions 114, and the size, the shape, and the position of the sacrificial growth portion 116.

The second specification calculating section 630 calculates the design specification of the inhibition portion 114 and the sacrificial growth portion 116, based on the mutual relation stored in the second storage section 632. The mutual relation stored in the second storage section 632 may be a mutual relation between the required specification of the device forming thin film 112 and the design specification of the inhibition portion 114 and the sacrificial growth portion 116. The second storage section 632 stores the mutual relation in a table format.

The specification storage section 640 stores the design specification of the device forming thin film 112, the inhibition portion 114, and the sacrificial growth portion 116 calculated by the first specification calculating section 620 and the second specification calculating section 630. The specification storage section 640, the first storage section 622, and the second storage section 632 may be a storage apparatus such as a hard disk and a semiconductor memory. The specification storage section 640, the first storage section 622, and the second storage section 632 may also be a storage apparatus such as a hard disk and a semiconductor memory, which is provided in a server system connected to a dedicated communication network or the Internet.

The output section 650 outputs the design specification of the device forming thin film 112, and the inhibition portion 114 and the sacrificial growth portion 116 stored in the specification storage section 640 (e.g., the position and the size of the inhibition portion 114 and the sacrificial growth portion 116). The output section 650 may include an output apparatus such as a display apparatus and a printer. The output section 650 may include a communication interface and a network communication apparatus, to transmit the data via a telecommunications line such as a dedicated communication network and the Internet.

The wafer design system 600 may be realized by hardware or software. The wafer design system 600 may be a system dedicated to the designing of a semiconductor device wafer, and may be a general information processing apparatus such as a PC. For example, the wafer design system 600 can be realized by activating the software defining the operation of the above-mentioned respective sections, in an information processing apparatus having a general configuration that includes a data processing apparatus, an input apparatus, an output apparatus, and a storage apparatus, the data processing apparatus including a CPU, a ROM, a RAM, a communication interface, and so on.

The wafer design system 600 may be realized by a wafer design program realizing the wafer design system 600 by controlling the above-mentioned information processing apparatus, or by a recording medium recording therein the wafer design program. The recording medium may be a magnetic recording medium such as a floppy (registered trademark) disk, a hard disk, etc., an optical . recording medium such as CD-ROM, a magneto-optical recording medium such as MD, and a semiconductor memory such as an IC card.

The program may be provided via a network to the information processing apparatus, by using, as a recording medium, a storage apparatus such as a hard disk or RAM provided in a server system connected to a dedicated communication network or the Internet. The dedicated system and the information processing apparatus may be constituted by a single computer, or a plurality of computers distributed on the network.

The wafer design program is read from the recording medium into the information processing apparatus, and controls the operation of the information processing apparatus. The information processing apparatus operates as the wafer design system 600 to design the semiconductor device wafer 100, under control of the wafer design program.

According to the above description, the following manufacturing apparatus of a semiconductor device wafer is disclosed. Specifically, disclosed is a manufacturing apparatus for a semiconductor device wafer that includes a thin film for making a semiconductor device, an inhibition portion that inhibits a precursor of the thin film from growing into a crystal, and a sacrificial growth portion that is positioned at a distance from a periphery of the thin film and stabilizes crystal growth of the thin film, the manufacturing apparatus including a first specification calculating section that determines a design specification of the thin film based on a required specification of the semiconductor device; and a second specification calculating section that determines a design specification of the inhibition portion and a design specification of the sacrificial growth portion based on the design specification of the thin film.

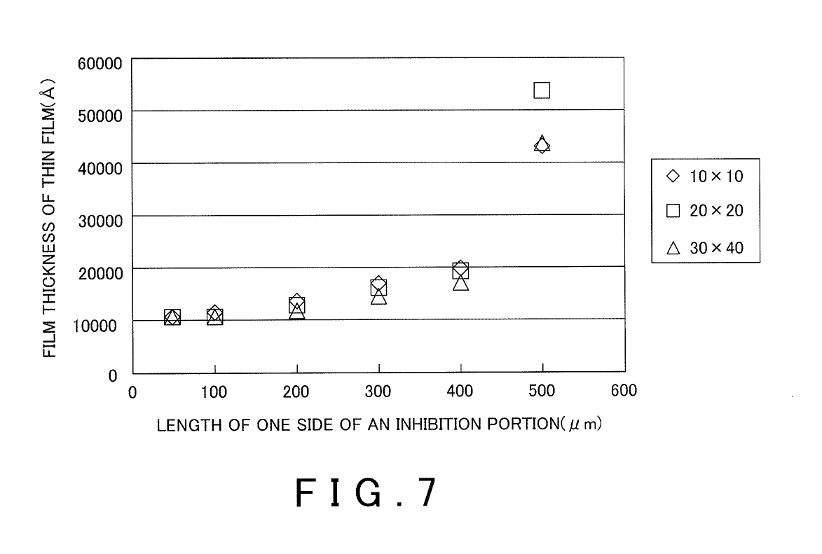

FIG. 7 shows, in a case where the device forming thin film 112 of FIG. 2 is formed at a prescribed temperature and a prescribed pressure, a relation between the length of a side of an inhibition portion 114 and the film thickness of the device forming thin film 112. The relation in FIG. 7 results when the inhibition portion 114 is shaped as a square in a plan view, and the length of a side of the inhibition portion 114 is equal to the distance between two adjacent inhibition portions 114. In this case, the region of the base wafer 110, in which no inhibition portion 114 is formed, functions as the sacrificial growth portion 116.

The diamond-shaped mark shows the film thickness when the device forming thin film 112 is shaped as a square in a plan view and L₁ and W₁ of FIG. 2 are 10 μm. The square mark shows the film thickness when the device forming thin film 112 has a square shape in a plan view and L₁ and W₁ are 20 μ. The triangular mark shows the film thickness when the device forming thin film 112 has a rectangular shape in a plan view and L₁ is 30 μm and W₁ is 40 μm.

As can be understood from FIG. 7, so as to form a device forming thin film 112 having the film thickness of 10000 Angstrom and a square shape in a plan view of which one side is 10 μm, the inhibition portion 114 has to be shaped as a square in a plan view of which one side is 50 through 100 μm, and the device forming thin film 112 has to be formed in the middle of the inhibition portion 114. In addition, the drawing suggests that, in the region in which the length of a side of the inhibition portion 114 is 50 μm through 400 μm, the device forming thin film 112 is formed under the condition where the supply of the precursor is the rate-controlling factor. In other words, in this region, the deposition rate does not depend on the growth temperature, and so the deposition rate can be determined by the length of the inhibition portion. Moreover, the drawing suggests that the film thickness of the device forming thin film 112 becomes instable when the length of the inhibition portion has reached 500 μm.

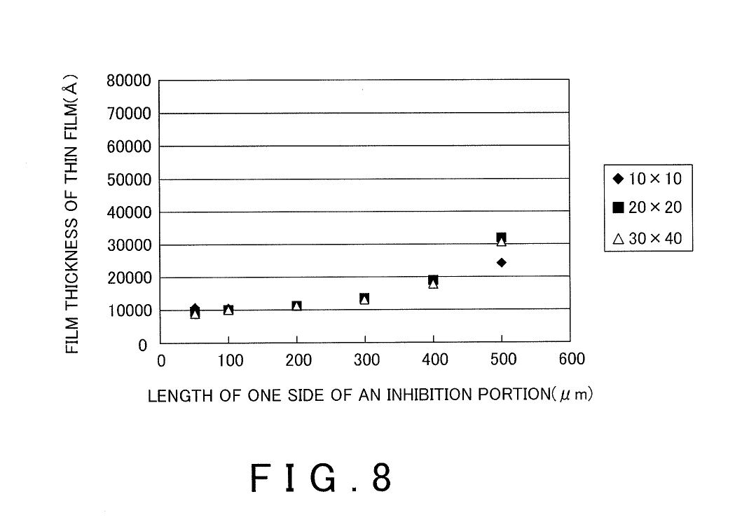

FIG. 8 shows another example of the mutual relation between the film thickness of the device forming thin film 112 and the size of the inhibition portion 114 in FIG. 2. FIG. 8 shows a relation between the length of a side of the inhibition portion 114 and the thickness of the device forming thin film 112 in a case where the device forming thin film 112 having a prescribed composition is formed at a prescribed temperature and a prescribed pressure. The device forming thin film 112 in FIG. 8 has been formed under the same condition as in FIG. 7, except the addition of a prescribed dopant.

The diamond-shaped mark shows the film thickness when the device forming thin film 112 is shaped as a square in a plan view and L₁ and W₁ of FIG. 2 are 10 μm. The square mark shows the film thickness when the device forming thin film 112 has a square shape in a plan view and L₁ and W₁ are 20 μm. The triangular mark shows the film thickness when the device forming thin film 112 has a rectangular shape in a plan view and L₁ is 30 μm and W₁ is 40 μm.

The mutual relation between the required specification of the device forming thin film 112 and the design specification of the inhibition portion 114 and the sacrificial growth portion 116 can be determined based on the data shown in FIG. 7 and FIG. 8. The second storage section 632 stores the mutual relation obtained using the data shown in FIG. 7 and FIG. 8 in a table format.

### EMBODIMENT EXAMPLES

### Embodiment Example 1

The semiconductor device wafer 100 and the semiconductor apparatus 460 shown in FIG. 2 are manufactured using the wafer design system 600 in the manufacturing method shown in FIG. 5. As the semiconductor device wafer 100, a SOI wafer, a seed layer of SiₓGe₁₋ₓ (x is from 0 to 0.1), a GaAs layer in contact with the seed layer are arranged in the stated order in the direction perpendicular to a main plane of the SOI wafer. As the semiconductor apparatus 460, HBT was designed, which uses the GaAs layer of the semiconductor device wafer 100 as an active layer. As the HBT, an HBT that uses GaAs as a base and a collector and InGaP as an emitter is designed.

Prior to the designing, the mutual relation obtained based on FIG. 7 and FIG. 8 is inputted to the second storage section 632 of the wafer design system 600. As the required specification of the semiconductor device, inputted was data obtained in the case where pairs respectively composed of a seed layer of SiₓGe₁₋ₓ (x is from 0 to 0.1) in contact with the base wafer 110 and an active layer of GaAs on the seed layer are arranged at each constant interval of 30 μm in a direction parallel to a main plane of the base wafer 110. The size of the active layer was set to be 10 μm by 10 μm. The film thickness of the seed layer and the active layer has been set to be 0.5 μm and 3 μm, respectively. Also inputted was information that indicates to allow annealing at the temperature of 900 degrees centigrade, in manufacturing the seed layer. An Si wafer is set to be the base wafer 110.

After storing the mutual relation in the wafer design system 600, the design specification of the device forming thin film 112, the inhibition portion 114, and the sacrificial growth portion 116 was calculated. The wafer design system 600 first calculated the required specification of the device forming thin film 112 based on the required specification of the semiconductor device, and then calculated the design specification of the inhibition portion 114 and the sacrificial growth portion 116 based on the required specification of the device forming thin film 112. The design specification of the inhibition portion 114 and the sacrificial growth portion 116 may also be calculated by inputting, to the wafer design system 600, the required specification of the device forming thin film 112 determined based on the required specification of the semiconductor device.

Consequently, the output indicating that the device forming thin films 112 of 10 μm by 10 μm can be arranged at each constant interval of 30 μm has been obtained. In addition, the output indicating that the inhibition portions 114 of which one side is 15 μm-20 μm can be arranged with the device forming thin film 112 at its center, that the portion of the base wafer 110 where no inhibition portion 114 has been formed can be used as a sacrificial growth portion 116, and that the device forming thin film 112 can be arranged at the center of the inhibition portion 114 has been obtained. Furthermore, the output indicating that SiO₂ whose thickness is 0.5 μm-1.0 μm can be formed as the inhibition portion 114 has been obtained.

The semiconductor device and the mask were designed based on the output from the wafer design system 600. The mask was designed so that the device forming thin films 112 of 10 μm by 10 μm are arranged at each constant interval of 30 μm. In addition, the designing was pursued so that the inhibition portions 114 of which one side is 20 μm can be arranged with the device forming thin film 112 at its center. The inhibition portion 114 has been designed so that the center of the device forming thin film 112 matches the center of the inhibition portion 114.

Using the above-described mask, the device forming thin films 112, the inhibition portions 114, and the sacrificial growth portions 116 have been formed on the base wafer 110. The seed layer and the active layer have been formed by CVD, thereby forming the semiconductor device wafer 100. The seed layer was deposited under the condition of the growth temperature of 600 degrees centigrade and the pressure within the reaction chamber being 2.6 kPa. After deposited, the seed layer was annealed for 10 minutes under the temperature of 850 degrees centigrade, and then for 10 minutes under the temperature of 780 degrees centigrade. The active layer was deposited under the condition of the growth temperature of 650 degrees centigrade and the pressure within the reaction chamber being 9.9 kPa. Using the above-described active layer, the semiconductor device is formed on the semiconductor device wafer 100, thereby forming the semiconductor apparatus 460.

When the device forming thin film 112 of the semiconductor device wafer 100 was observed using the SEM, the film thickness of the seed layer was 0.5 μm, and the film thickness of the active layer was 2.5 μm. Moreover, as a result of examination by the etch-pit method, no defect was observed on the surface of the active layer. Furthermore, as a result of conducting in-plane sectional observation on the semiconductor apparatus 460 using the TEM, no defect was found. In addition, the semiconductor apparatus 460 operated as designed. As described above, the device forming thin film 112 satisfying the required specification of both of the film thickness and the film quality has been formed using the wafer design system 600.

### Embodiment Example 2

In Embodiment Example 2, the fact that the growth rate of the device forming thin film changes by varying the width of the inhibition portion is described based on the experimental data of the inventors of the present invention. The growth rate of the device forming thin film affects the characteristics of the device forming thin film such as flatness, the crystallinity or the like. The characteristics of the device forming thin film affect the performance of the semiconductor device formed on the device forming thin film to a great extent. Therefore, it is required to control the growth rate of the device forming thin film in an appropriate manner so as to satisfy the required characteristics of the device forming thin film conforming to the required specification of the device forming thin film. The experimental data described as follows shows that the growth rate of the device forming thin film changes due to the width of the inhibition portion or the like. Therefore by using the experimental data, it becomes possible to design the shape of the inhibition portion to be able to set an appropriate growth rate of the device forming thin film conforming to the required specification of the device forming thin film.

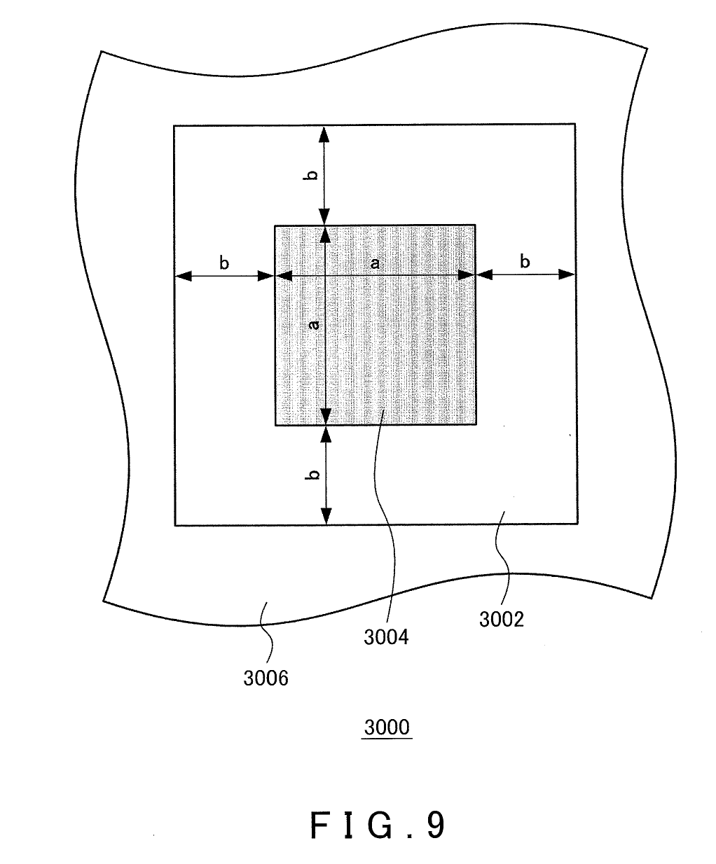

FIG. 9 illustrates a plan view illustrating a semiconductor device wafer 3000 manufactured in Exemplary Embodiment 2. The semiconductor device wafer 3000 has an inhibition portion 3002, a device forming thin film 3004, and a sacrificial growth portion 3006 on a base wafer. The inhibition portion 3002, the device forming thin film 3004, and the sacrificial growth portion 3006 were formed such that the inhibition portion 3002 surrounds the device forming thin film 3004 and the sacrificial growth portion 3006 surrounds the inhibition portion 3002.

The inhibition portion 3002 was formed so as to have a substantially square outline and have a substantially square opening at the center of the square. The length of the side a of the opening was set at 30 μm or 50 μm. The width b of the inhibition portion 3002, which is defined as the distance between the outer periphery of the inhibition portion 3002 and the inner periphery of the inhibition portion 3002 varied within the range of 5 μm to 20 μm. The inhibition portion 3002 was made of silicon dioxide (SiO₂). No crystals are epitaxially grown on the surface of the silicon dioxide layer when the epitaxial growth conditions were adapted to realize selective MOCVD. The inhibition portion 3002 was formed by forming a silicon dioxide film on a base wafer by dry thermal oxidization and by patterning the silicon dioxide film by photolithography.

A compound semiconductor crystal was selectively epitaxially grown by MOCVD on a portion of the base wafer in which the inhibition portion 3002 was not formed. The compound semiconductor crystal that is epitaxially grown in the opening surrounded by the inhibition portion 3002 constitutes the device forming thin film 3004, and the compound semiconductor crystal that externally surrounds the inhibition portion 3002 constitutes the sacrificial growth portion 3006. The compound semiconductor crystal was a GaAs crystal, an InGaP crystal, or a p-type doped GaAs crystal (p-GaAs crystal). The Ga source was trimethyl gallium (Ga(CH₃)₃) and the As source was arsine (AsH₃). The In source was trimethyl indium (In(CH₃)₃) and the P source was phosphine (PH₃). Doping with carbon (C), which served as p-type impurities, was controlled by adjusting the added amount of bromotrichloromethane (CBrCl₃), which served as dopants. The epitaxial growth was carried out at the temperature of 610° C.

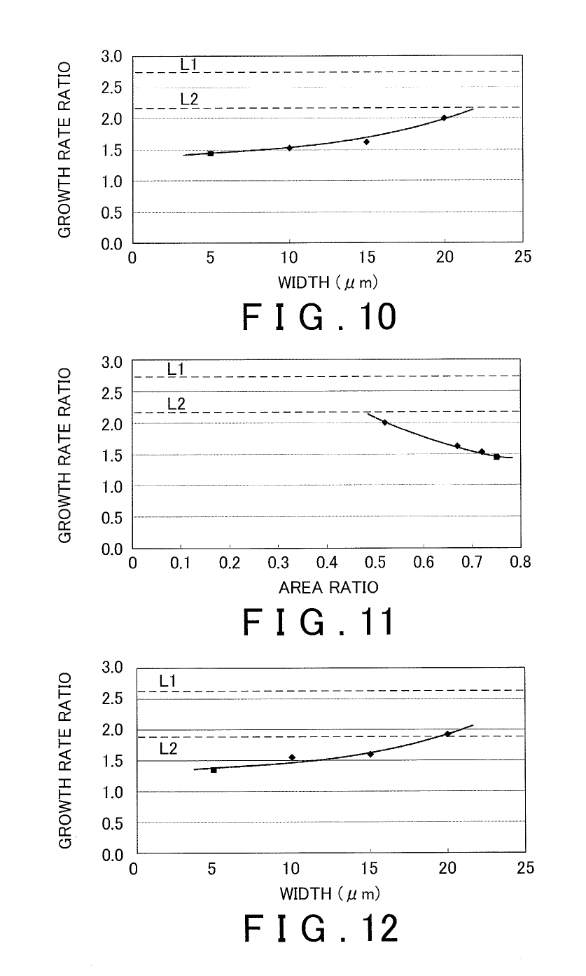

FIG. 10 is a graph showing how the growth rate of the device forming thin film 3004 is dependent on the width of the inhibition portion 3002 when GaAs is epitaxially grown to form the device forming thin film 3004 and the sacrificial growth portion 3006. FIG. 11 is a graph showing how the growth rate of the device forming thin film 3004 is dependent on its area ratio when GaAs is epitaxially grown to form the device forming thin film 3004 and the sacrificial growth portion 3006. FIG. 12 is a graph showing how the growth rate of the device forming thin film 3004 is dependent on the width of the inhibition portion 3002 when InGaP is epitaxially grown to form the device forming thin film 3004 and the sacrificial growth portion 3006.

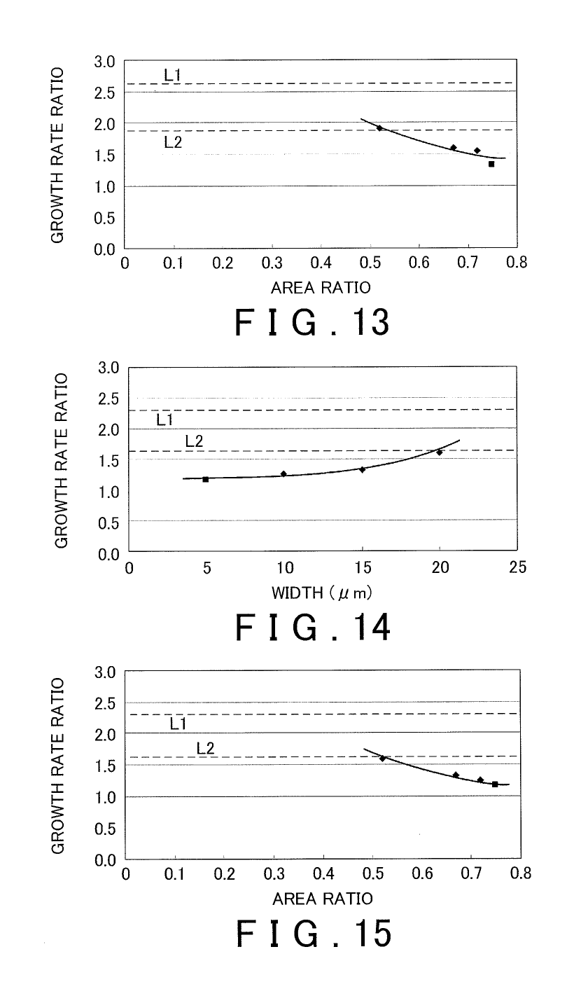

FIG. 13 is a graph showing how the growth rate of the device forming thin film 3004 is dependent on its area ratio when InGaP is epitaxially grown to form the device forming thin film 3004 and the sacrificial growth portion 3006. FIG. 14 is a graph showing how the growth rate of the device forming thin film 3004 is dependent on the width of the inhibition portion 3002 when p-GaAs is epitaxially grown to form the device forming thin film 3004 and the sacrificial growth portion 3006. FIG. 15 is a graph showing how the growth rate of the device forming thin film 3004 is dependent on its area ratio when p-GaAs is epitaxially grown to form the device forming thin film 3004 and the sacrificial growth portion 3006.

In FIGS. 10 to 15, the vertical axis represents the growth rate ratio of the compound semiconductor crystal. The growth rate ratio is defined in comparison with the growth rate of the compound semiconductor crystal on a plain plane that does not have the inhibition portion 3002 where the plain plane is assumed to have a growth rate of 1. The area ratio is defined as the ratio of the area of the region in which the device forming thin film 3004 to the total of the area of the region in which the device forming thin film 3004 is formed and the area of the region in which the inhibition portion 3002 is formed.

In FIGS. 10 to 15, the black square or diamond marks are actually measured values. The solid lines represent experimental lines. The experimental lines were each a quadratic function with one variable, and the coefficients of each polynomial were calculated by the least squares method. For the comparison purposes, the growth rate ratio calculated when the device forming thin film 3004 was grown without the sacrificial growth portion 3006 is indicated by the dotted lines. The dotted lines L₁ correspond to the case where the area of the opening in the inhibition portion 3002 is 50 μm□, and the dotted lines L₂ correspond to the case where the area of the opening in the inhibition portion 3002 is 30 μm². The case of “without the sacrificial growth portion 3006” is the case where the inhibition portion 3002 covers the region corresponding to the sacrificial growth portion 3006.

As seen from FIGS. 10 to 15, as the width of the inhibition portion 3002 increased, the growth rate increased, and as the area ratio decreased, the growth rate increased. In addition, the actually measured values agreed well with the experimental lines. Therefore, it is found that the inhibition portion 3002 can be designed using the quadratic-function experiment lines in a manner that a desired growth rate may be realized.

The above-described experimental results can be explained when the following crystal growth mechanism is taken into consideration. The Ga and As atoms, from which the deposited crystals are formed, are thought to be supplied by the molecules that fly from a space or move over a surface. The named inventors of the present invention think that the dominant supply source is the molecules that move over a surface in the case of the reaction environment in which selective epitaxial growth takes place based on MOCVD. Specifically speaking, the source molecules (precursors) that fly to the inhibition portion 3002, excluding some escaping from the surface, migrate along the surface of the inhibition portion 3002 to be supplied to the device forming thin film 3004 or the sacrificial growth portion 3006. Here, as the width of the inhibition portion 3002 increases, the absolute number of the source molecules supplied by the surface migration increases, thereby increasing the growth rate of the device forming thin film 3004. Also, as the ratio of the area of the device forming thin film 3004 to the total area decreases, the source molecules supplied from the inhibition portion 3002 to the device forming thin film 3004 relatively increases. This results in a higher growth rate of the device forming thin film 3004.

Bearing the above-described growth mechanism in mind, the function of the sacrificial growth portion 3006 can be understood as follows. If the sacrificial growth portion 3006 is not provided, the source molecules are excessively supplied to the device forming thin film 3004. This will disturb the surface of the device forming thin film 3004 and degrade the crystallinity of the device forming thin film 3004. In other words, the sacrificial growth portion 3006 serves to take in an appropriate portion of the source molecules that fly to the inhibition portion 3002, thereby appropriately controlling the amount of the source molecules supplied to the device forming thin film 3004. It can be said that the sacrificial growth portion 3006 has a function of preventing the source molecules from being excessively supplied to the device forming thin film 3004 by consuming some of the source molecules through sacrificial growth.

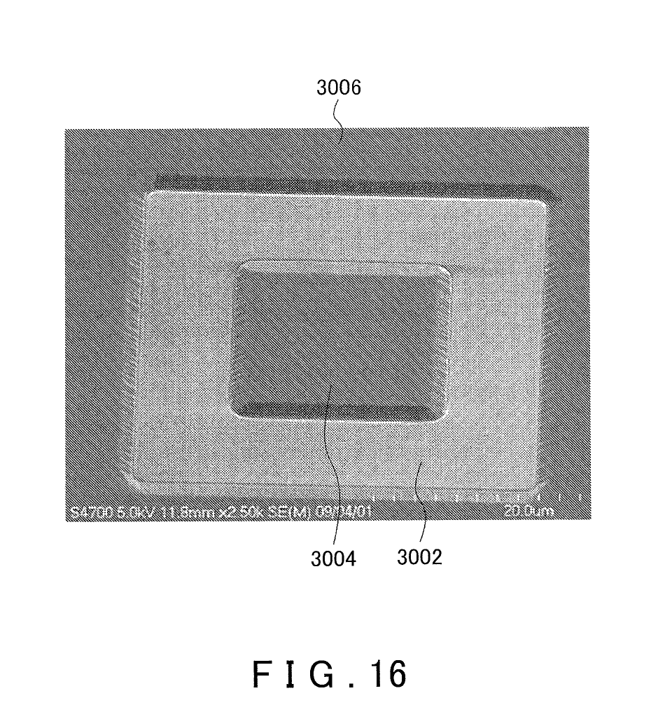

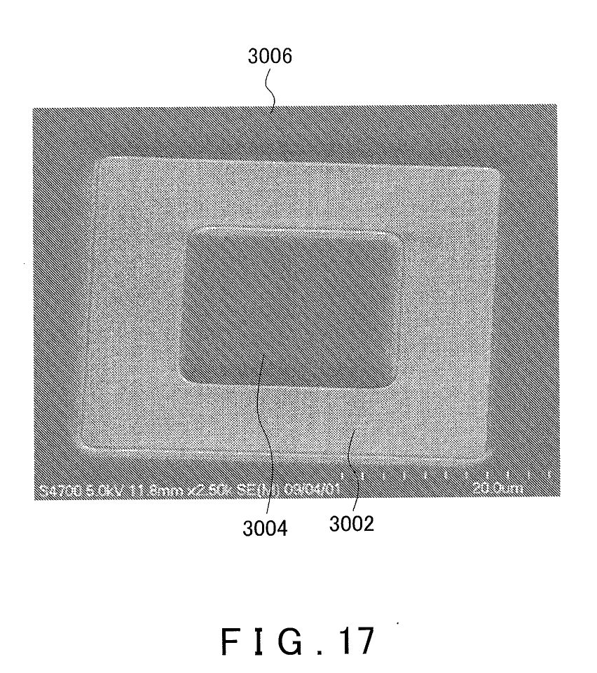

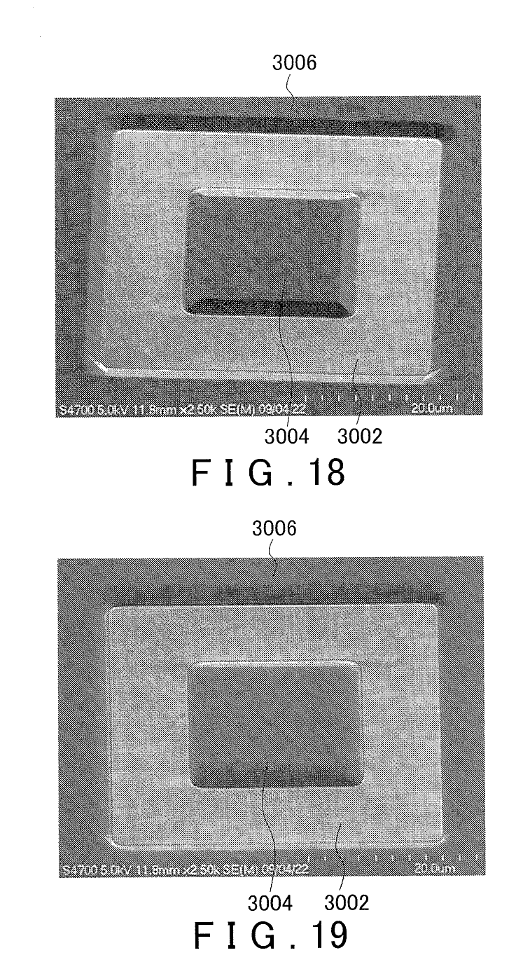

FIGS. 16 and 17 are electron micrographs showing the surface of the semiconductor device wafer 3000 in which the base wafer has an off angle of 2 degrees. FIG. 16 shows the state after epitaxial growth and FIG. 17 shows the state after annealing. FIGS. 18 and 19 are electron micrographs showing the surface of the semiconductor device wafer 3000 in which the base wafer has an off angle of 6 degrees. FIG. 18 shows the state after epitaxial growth and FIG. 19 shows the state after annealing. Here, the off angle is defined as the angle formed between the surface of the silicon constituting the base wafer and the crystallographically defined (100) plane.

As seen from FIGS. 16 to 18, the crystal surface was less rough when the off angle is 2 degrees than when the off angle is 6 degrees. Therefore, the off angle of 2 degrees is preferable to the off angle of 6 degrees. As seen from FIGS. 17 to 19, an excellent crystal surface was obtained after annealing whether the off angle was 2 degrees or 6 degrees. Therefore, it was proved that a crystal with good quality could be grown when the off angle falls in the range from 2 degrees to 6 degrees.

### Exemplary Embodiment 3

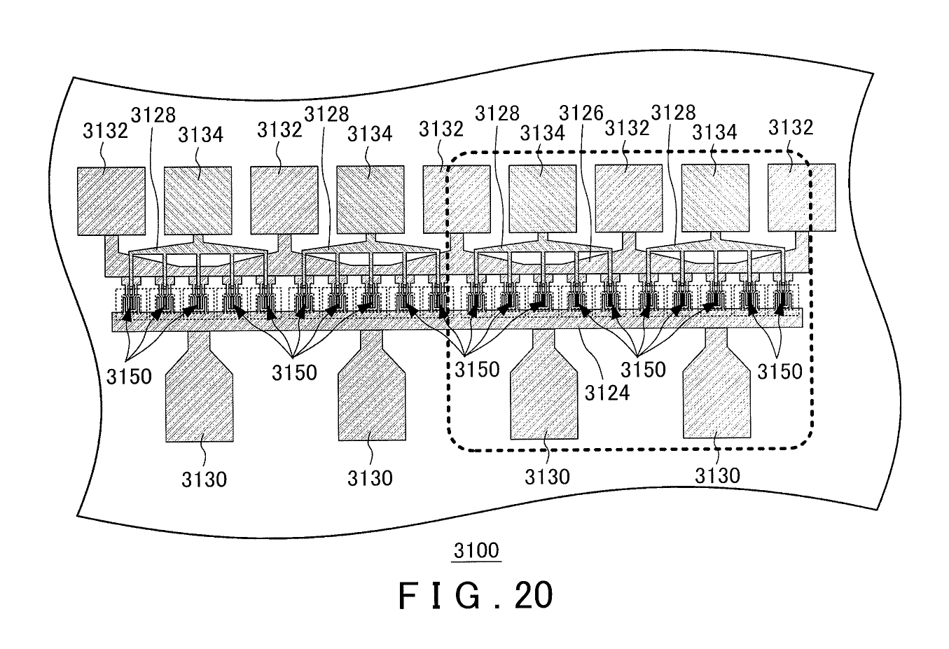

FIG. 20 is a plan view illustrating a heterojunction bipolar transistor (HBT) 3100 manufactured by the named inventors of the present invention. The HBT 3100 is structured such that 20 HBT elements 3150 are connected in parallel. Note that FIG. 20 only shows a part of the base wafer in which one HBT 3100 is formed. The same base wafer has a test pattern and other semiconductor elements formed thereon, but they are not described here.

The collectors of the 20 HBT elements 3150 were connected in parallel by means of a collector interconnection 3124, the emitters were connected in parallel by means of an emitter interconnection 3126, and the bases were connected in parallel by means of base interconnections 3128. Note that the 20 bases were divided into four groups, so that five bases of each group were connected in parallel. The collector interconnection 3124 was connected to collector pads 3130, the emitter interconnection 3126 was connected to emitter pads 3132, and the base interconnections 3128 were connected to base pads 3134. The collector interconnection 3124, the collector pads 3130, the emitter interconnection 3126, and the emitter pads 3132 were formed in the same first interconnection layer, and the base interconnections 3128 and the base pads 3134 were formed in a second interconnection layer, which was above the first interconnection layer.

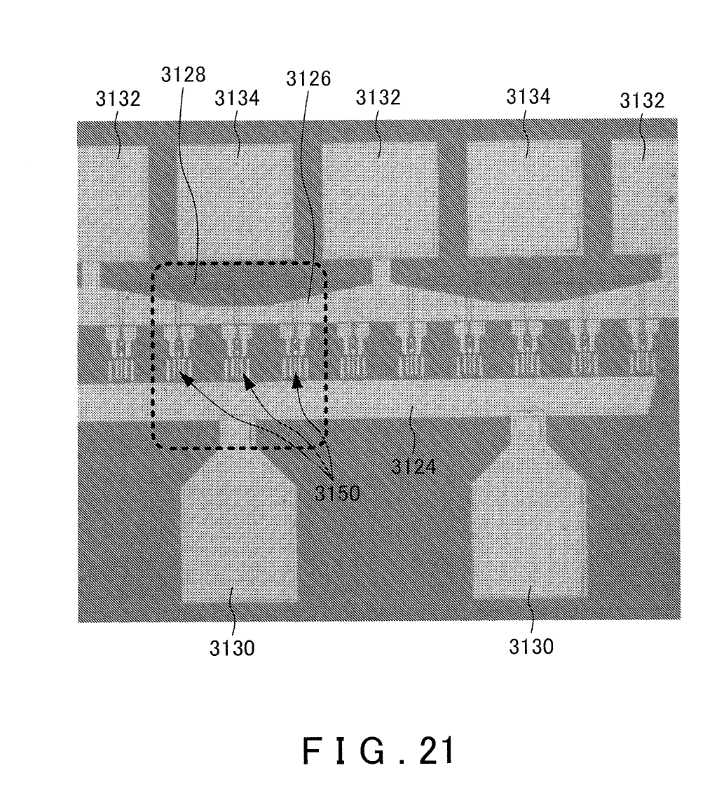

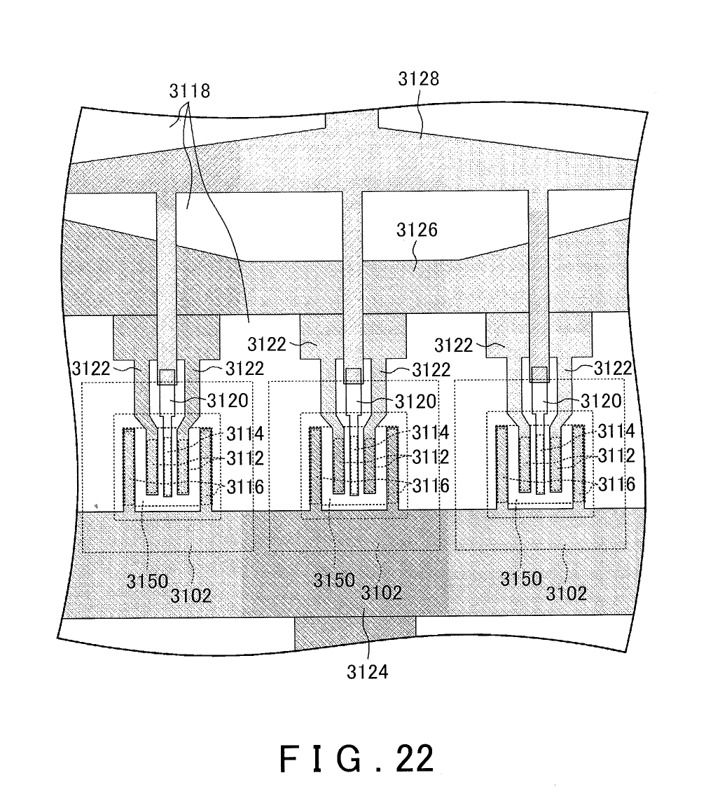

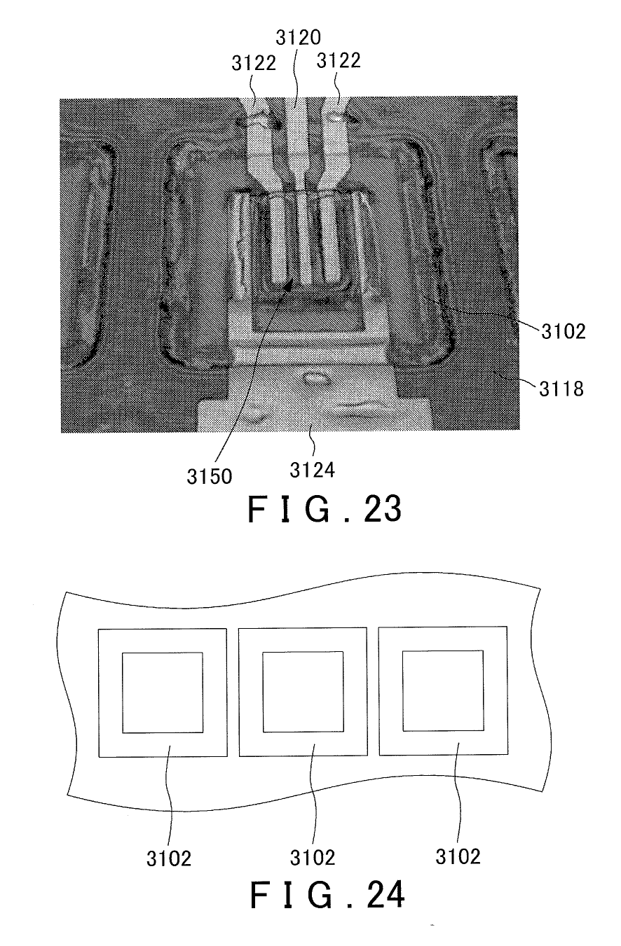

FIG. 21 is an electron micrograph showing the portion enclosed by the dashed line in FIG. 20 FIG. 22 is an enlarged plan view illustrating the three HBT elements 3150 enclosed by the dashed line in FIG. 21. The collector interconnection 3124 was connected to collector electrodes 3116, the emitter interconnection 3126 was connected to emitter electrodes 3112 via emitter extension interconnections 3122, and the base interconnections 3128 were connected to base electrodes 3114 via base extension interconnections 3120. Below the collector interconnection 3124, the emitter extension interconnections 3122, and the base extension interconnections 3120, a field insulating film 3118 was formed that insulates the HBT elements 3150 and the sacrificial growth portion from the collector interconnection 3124, the emitter extension interconnections 3122, and the base extension interconnections 3120. Below the field insulating film 3118, an inhibition portion 3102 was formed. Each HBT element 3150 was formed in a region surrounded by the inhibition portion 3102. FIG. 23 is a laser electron microscopic image showing the region of the HBT element 3150.

FIGS. 24 to 28 are plan views illustrating the sequential steps of the manufacturing process of the HBT 3100. The base wafer was a silicon wafer. A silicon dioxide film was formed by dry thermal oxidization on the base wafer. After this, the silicon dioxide film was patterned by photolithography into the inhibition portions 3102 as shown in FIG. 24.

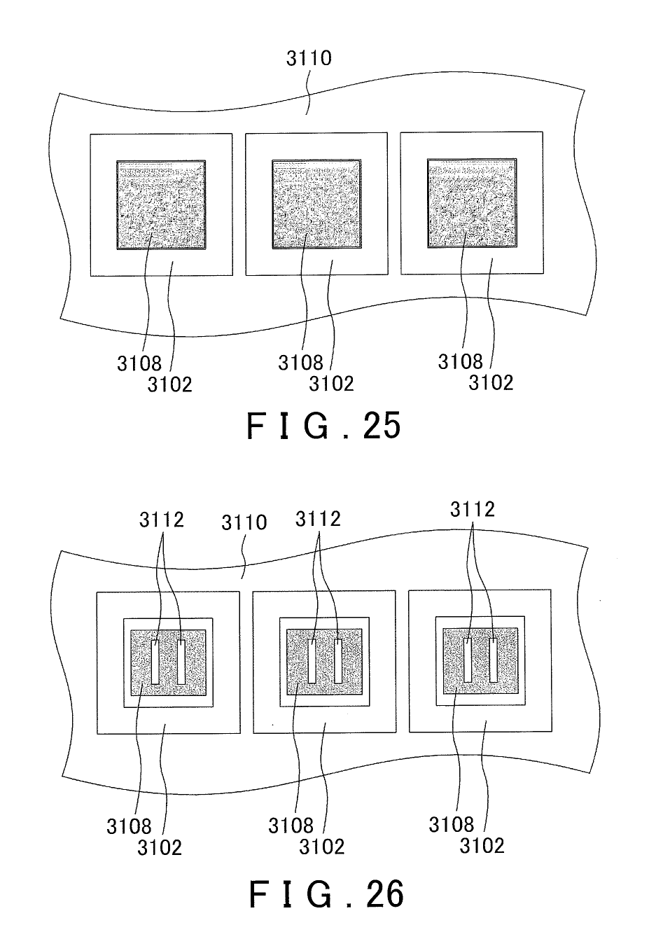

As shown in FIG. 25, selective epitaxial growth was used for forming device forming thin films 3108 in the regions enclosed by the inhibition portions 3102 and sacrificial growth portions 3110 in the regions surrounding the inhibition portions 3102. The device forming thin films 3108 were each formed by sequentially stacking, on the silicon wafer that is provided as the base wafer, a Ge seed layer, a buffer layer, a sub-collector layer, a collector layer, a base layer, an emitter layer, and a sub-emitter layer. While the device forming thin films 3108 were being formed, the flow rate of arsine was reduced to zero after the emitter layers were grown and before the sub-emitter layers were grown and annealing was performed under a hydrogen gas atmosphere at the temperature of 670 degrees centigrade for a duration of 3 minutes.

As shown in FIG. 26, the emitter electrodes 3112 were formed in the device forming thin films 3108 and used as masks to form emitter mesas in the device forming thin films 3108. In the step of forming the emitter mesas, the device forming thin films 3108 were etched to such a depth that the base layers were exposed. After this, collector mesas were formed in the region in which the collector electrodes 3116 were to be formed. In the step of forming the collector mesas, the device forming thin films 3108 were etched to such a depth that the sub-collector layers were exposed. Furthermore, the peripheral portions of the device forming thin films 3108 were etched to forming isolation mesas.

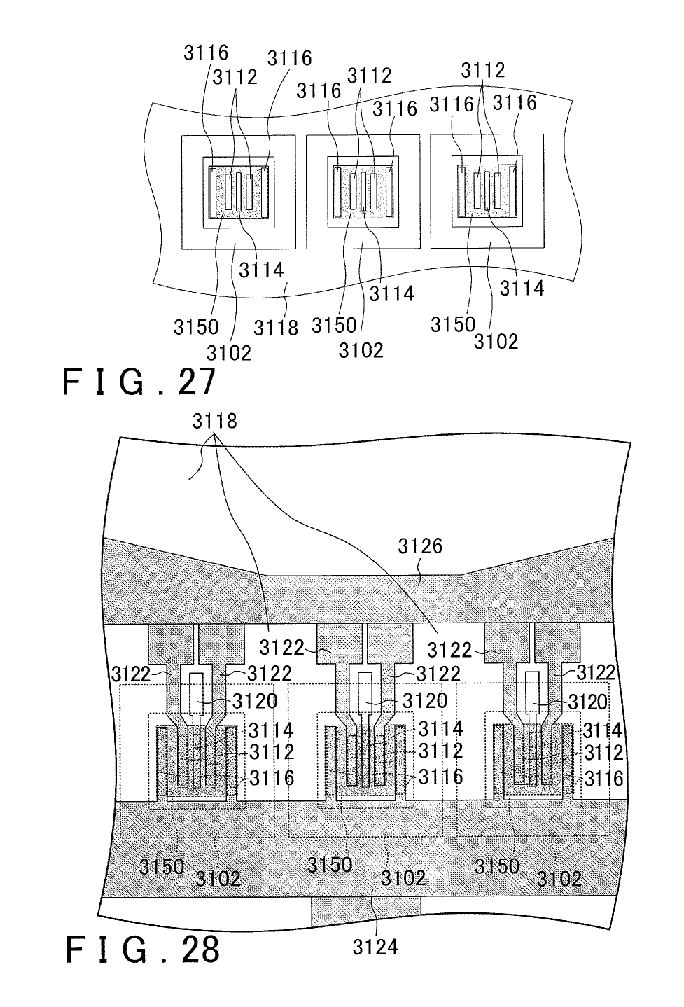

As shown in FIG. 27, a silicon dioxide film was deposited on the entire surface to form the field insulating film 3118. In the field insulating film 3118, connection holes were bored to expose the base layers, so that the base electrodes 3114 were formed. Furthermore, connection holes were bored in the field insulating film 3118 to expose the sub-collector layers, so that the collector electrodes 3116 were formed. The emitter electrodes 3112, the base electrodes 3114, and the collector electrodes 3116 were formed by multilayer films constituted by nickel (Ni) and gold (Au). The emitter electrodes 3112, the base electrodes 3114, and the collector electrodes 3116 were formed by the lift-off method. In the above-described manner, the HBT elements 3150 were formed.

As shown in FIG. 28, the emitter extension interconnections 3122 connected to the emitter electrodes 3112, the emitter interconnection 3126 connected to the emitter extension interconnections 3122, the base extension interconnections 3120 connected to the base electrodes 3114, and the collector interconnection 3124 connected to the collector electrodes 3116 were formed. The emitter extension interconnection 3122, the emitter interconnection 3126, the base extension interconnections 3120, and the collector interconnection 3124 were made of aluminum. Furthermore, a polyimide film was formed as an inter-layer insulating layer on the entire surface so as to cover the emitter extension interconnections 3122, the emitter interconnection 3126, the base extension interconnections 3120, and the collector interconnection 3124. On the inter-layer insulating layer, the base interconnections 3128 were formed so as to be connected to the base extension interconnections 3120 via the connection holes. In the above-described manner, the HBT 3100 shown in FIG. 22 was formed.

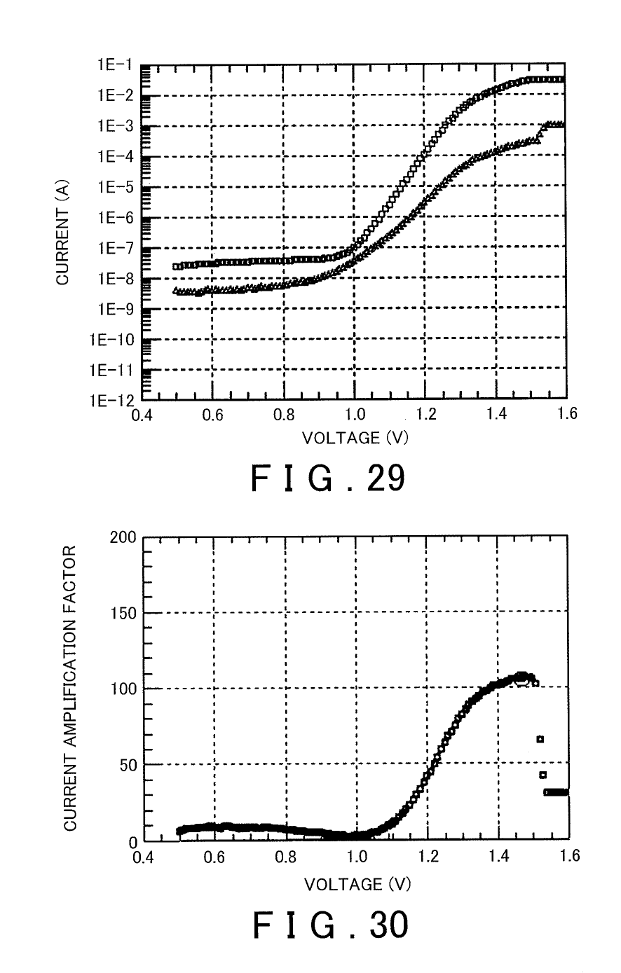

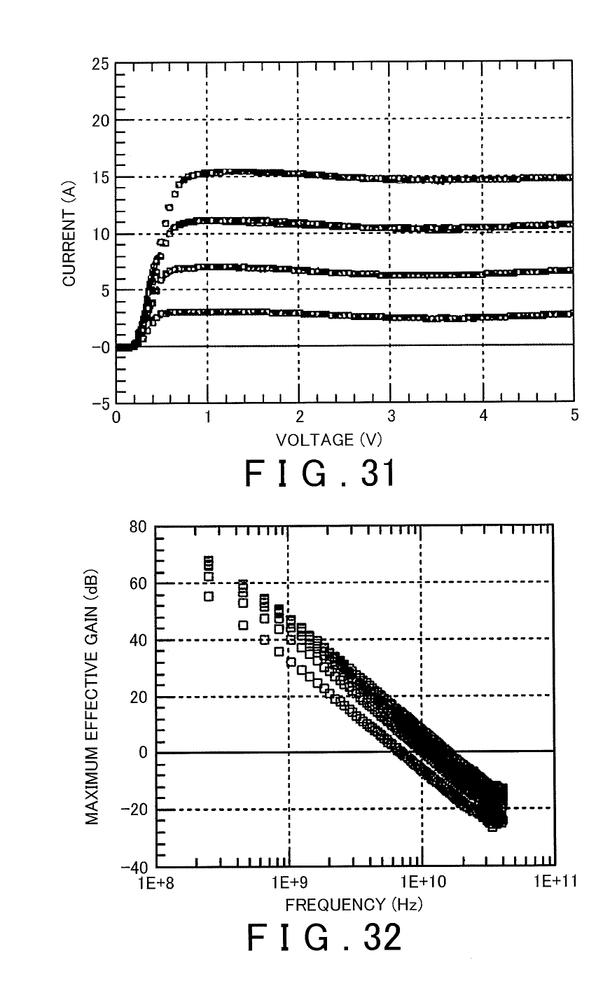

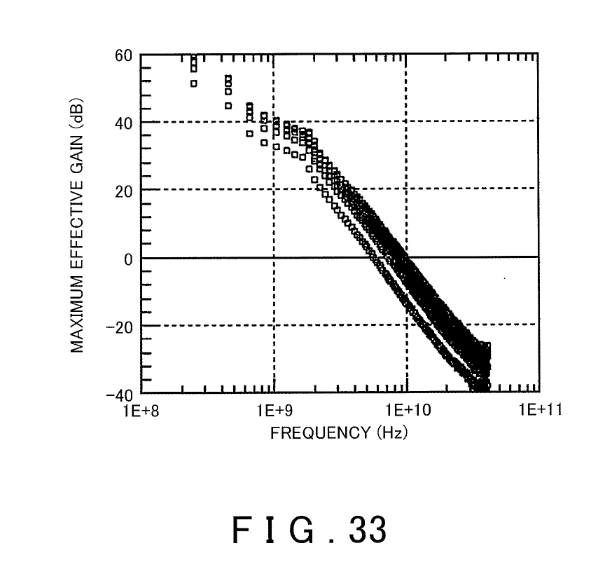

FIGS. 29 to 33 are graphs showing the data obtained by measuring the various characteristics of the manufactured HBT 3100. FIG. 29 shows how the collector current and the base current vary depending on the base-emitter voltage. The square marks show the collector current, and the triangular marks show the base current. FIG. 30 shows how the current gain varies depending on the base-emitter voltage. The current gain started increasing when the base-emitter voltage reached approximately 1.15 V, and took the maximum value of 106 when the base-emitter voltage reached 1.47 V. FIG. 31 shows how the collector current varies depending on the collector voltage. FIG. 31 shows four different data sequences obtained by setting the base voltage at various values. FIG. 31 indicates that the collector current remained stable within a broad range of the collector voltage. FIG. 32 shows experimental data used for calculating such a cutoff frequency that the current gain takes a value of 1. When the base-emitter voltage was 1.5 V, the cutoff frequency took a value of 15 GHz. FIG. 33 shows experimental data used for calculating such a maximum oscillation frequency that the current gain takes a value of 1. When the base-emitter voltage was 1.45 V, the maximum oscillation frequency took a value of 9 GHz.

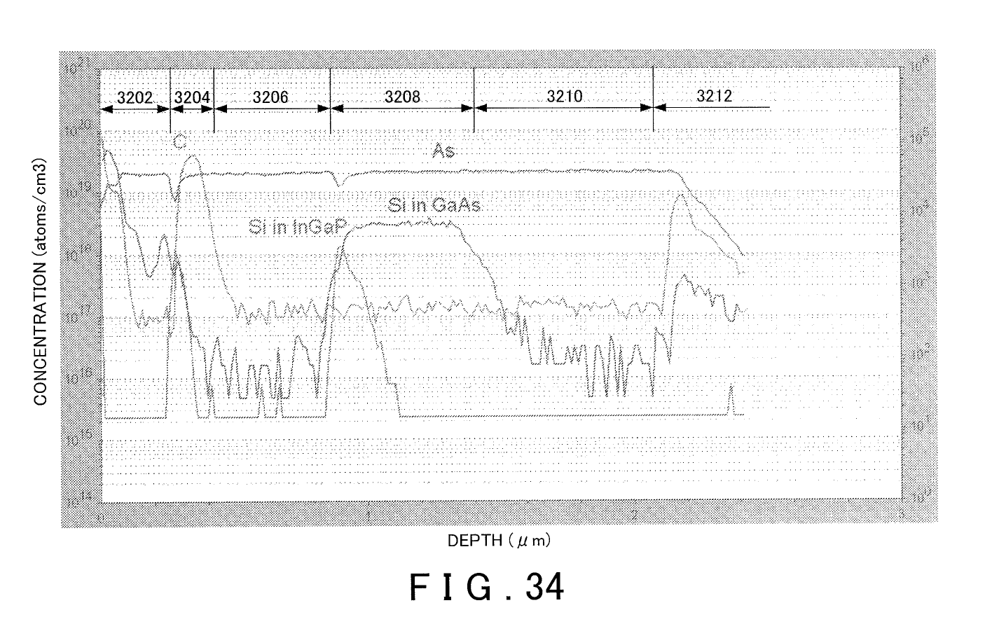

FIG. 34 shows the data obtained by measuring the depth profile based on secondary ion mass spectroscopy in the step of forming the device forming thin films 3108. The As atom concentration, the C atom concentration, the Si atom concentration within InGaAs, and the Si atom concentration within GaAs are shown in association with the depth. A range 3202 corresponds to GaAs and InGaP forming the sub-emitter layer and the emitter layer. A range 3204 corresponds to p-GaAs forming the base layer. A range 3206 corresponds to n⁻GaAs forming the collector layer. A range 3208 corresponds to n⁺GaAs forming the sub-collector layer and InGaP forming the etch stop layer. A range 3210 corresponds to GaAs and AlGaAs forming the buffer layer. A range 3212 corresponds to Ge forming the seed layer.

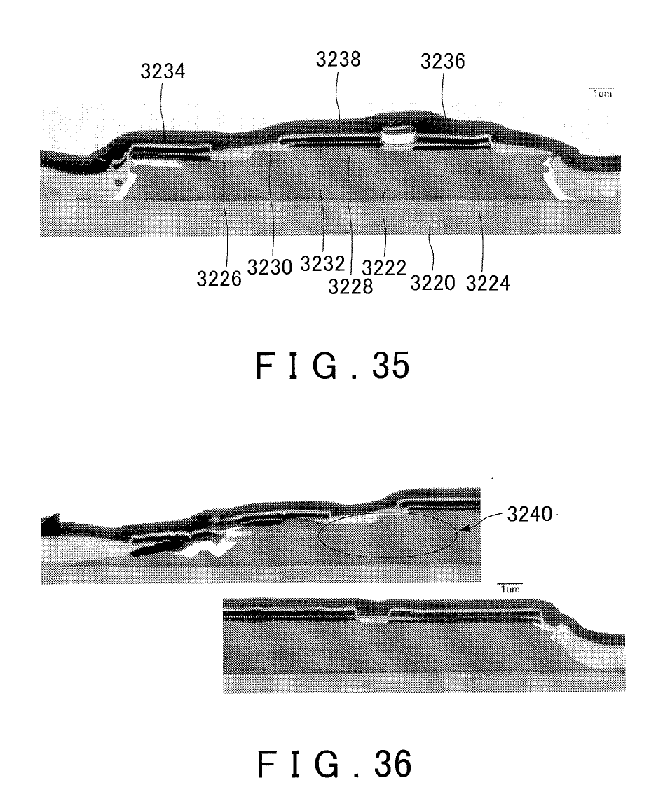

FIG. 35 is a TEM photograph showing the cross-section of a HBT concurrently manufactured with the HBT 3100. A Ge layer 3222, a buffer layer 3224, a sub-collector layer 3226, a collector layer 3228, a base layer 3230, a sub-emitter layer, and an emitter layer 3232 are sequentially formed on silicon 3220. A collector electrode 3234 is formed in contact with the sub-collector layer 3226, a base electrode 3236 is formed in contact with the base layer 3230, and an emitter electrode 3238 is formed in contact with the emitter layer 3232.

FIG. 36 is a TEM photograph provided for the comparison purposes, and shows an HBT manufactured by forming a device forming thin film on a plain wafer without an inhibition portion. A large number of crystal defects are present in a region 3240, and those defects reach the emitter-base-collector region, which constitutes the active region of the HBT. On the other hand, very few crystal defects are present in the HBT shown in FIG. 35. The HBT shown in FIG. 35 achieved a maximum current gain of 123, but the HBT shown in FIG. 36 only realized a maximum current gain of 30.

Although some aspects of the present invention have been described by way of exemplary embodiments, the technical scope of the present invention is not limited to the above-described embodiments. It is obvious for the person skilled in the art to change or improve the above-described embodiments in various manners within the scope of the appended claims, and such changes or improvements may be also considered to fall within the technical scope of the present invention.

### DESCRIPTION OF REFERENCE NUMERALS

100 semiconductor device wafer
110 base wafer
112 device forming thin film
114 inhibition portion
116 sacrificial growth portion
460 semiconductor apparatus
600 wafer design system
610 input section
620 first specification calculating section
622 first storage section
630 second specification calculating section
632 second storage section
640 specification storage section
650 output section
812 device forming thin film
822 device forming thin film
824 core region
826 sub region
3000 semiconductor device wafer
3002 inhibition portion
3004 device forming thin film
3006 sacrificial growth portion
3100 HBT
3102 inhibition portion
3108 device forming thin film
3110 sacrificial growth portion
3112 emitter electrode
3114 base electrode
3116 collector electrode
3118 field insulating film
3120 interconnection
3122 interconnection
3124 collector interconnection
3126 emitter interconnection
3128 base interconnection
3130 collector pad
3132 emitter pad
3134 base pad
3150 HBT element
3202 range
3204 range
3206 range
3208 range
3210 range
3212 range
3220 silicon
3224 buffer layer
3226 sub-collector layer
3230 base layer
3232 emitter layer
3234 collector electrode
3236 base electrode
3238 emitter electrode

1. A semiconductor device wafer comprising:
a device forming thin film for forming a semiconductor device;
an inhibition portion that surrounds the device forming thin film and inhibits growth of a precursor of the device forming thin film into a crystal; and
a sacrificial growth portion that is formed by causing the precursor to sacrificially grow into a crystal, and is positioned around the device forming thin film separated by the inhibition portion.

2. The semiconductor device wafer as set forth in claim 1, further comprising:
a protection film that covers a top portion of the sacrificial growth portion and exposes a top portion of the device forming thin film.

3. The semiconductor device wafer as set forth in claim 2, wherein
the protection film is made of polyimide.

4. The semiconductor device wafer as set forth in claim 2, wherein
the protection film is a multilayer film which has a silicon oxide film and a silicon nitride film stacked to each other.

5. The semiconductor device wafer as set forth in claim 1, comprising:
a plurality of sacrificial growth portions around the device forming thin film.

6. The semiconductor device wafer as set forth in claim 5, wherein
the plurality of sacrificial growth portions around the device forming thin film are positioned so as to be point symmetric to each other, with respect to the device forming thin film.

7. The semiconductor device wafer as set forth in claim 5, further comprising:
a base wafer, wherein
the device forming thin film and the plurality of sacrificial growth portions each have the same shape, and are positioned at constant intervals in two directions orthogonal to each other on the base wafer.

8. The semiconductor device wafer as set forth in claim 1, further comprising:
a base wafer made of silicon, wherein
the device forming thin film is a compound semiconductor formed on the silicon of the base wafer by crystal growth.

9. The semiconductor device wafer as set forth in claim 8, wherein the device forming thin film and the sacrificial growth portion each include SiₓGe₁₋ₓ (0≦X<1) formed on the silicon of the base wafer by crystal growth and a group III-V compound semiconductor lattice matched or pseudo lattice matched to the SiₓGe₁₋ₓ.

10. The semiconductor device wafer as set forth in claim 9, wherein
the SiₓGe₁₋ₓ has been annealed.

11. The semiconductor device wafer as set forth in claim 8, wherein
a surface of the silicon on which the device forming thin film is formed by crystal growth has an off angle tilted from one crystal plane selected from among the (100) plane, the (110) plane, the (111) plane, a plane crystallographically equivalent to the (100) plane, and a plane crystallographically equivalent to the (110) plane, and a plane crystallographically equivalent to the (111) plane.

12. The semiconductor device wafer as set forth in claim 11, wherein
the off angle is between 2 and 6 degrees, inclusive.

13. The semiconductor device wafer as set forth in claim 1, wherein
the maximum width of the device forming thin film is no greater than 50 μm.

14. The semiconductor device wafer as set forth in claim 13, wherein
the maximum width of the device forming thin film is no greater than 30 μm.

15. The semiconductor device wafer as set forth in claim 1, wherein
the maximum width of an outline of the inhibition portion is no greater than 400 μm.

16. The semiconductor device wafer as set forth in claim 1, produced by:
preparing a semiconductor wafer including a base wafer and an insulating layer that functions as the inhibition portion;
determining a size, a shape, and a position of the sacrificial growth portion based on a required specification of the device forming thin film;
forming, through the insulating layer, an opening in which the device forming thin film is to be positioned and an opening in which the sacrificial growth portion is to be positioned, the openings exposing the base wafer; and
simultaneously forming, by crystal growth, the device forming thin film and the sacrificial growth portion in the opening in which the device forming thin film is to be positioned and in the opening in which the sacrificial growth portion is to be positioned respectively.

17. The semiconductor device wafer as set forth in claim 1, wherein
a semiconductor device is formed on the device forming thin film, and
a semiconductor device capable of being used by a user using a finished semiconductor device product other than the semiconductor device formed on the device forming thin film is not formed in the sacrificial growth portion.

18. The semiconductor device wafer as set forth in claim 1, wherein
a TEG is formed in the sacrificial growth portion.

19. A semiconductor device apparatus obtained by dicing the semiconductor device wafer as set forth in claim 1.

20. A design system for designing a semiconductor device wafer including: a device forming thin film for forming a semiconductor device; an inhibition portion for inhibiting growth of a precursor of the device forming thin film into a crystal; and a sacrificial growth portion that is formed by causing the precursor to sacrificially grow into a crystal, the design system comprising:
a storage section that stores a mutual relation between a required specification of the device forming thin film and a design specification of the inhibition portion and the sacrificial growth portion; and
a specification calculating section that determines a position and a size of the inhibition portion and a position and a size of the sacrificial growth portion, based on the mutual relation stored in storage section and the required specification of the device forming thin film.

21. A manufacturing method of a semiconductor device wafer in which a device forming thin film is formed, by crystal growth, on a base wafer made of silicon, the manufacturing method comprising:
preparing a semiconductor wafer that includes the base wafer and an insulating layer that functions as an inhibition portion inhibiting growth of a precursor of the device forming thin film into a crystal;
forming, through the insulating layer, an opening in which the device forming thin film is to be positioned and an opening in which a sacrificial growth portion being formed by causing the precursor to sacrificially grow into a crystal is to be positioned, the openings exposing the base wafer; and
supplying the precursor to simultaneously form, by crystal growth, the device forming thin film and the sacrificial growth portion in the opening in which the device forming thin film is to be positioned and in the opening in which the sacrificial growth portion is to be positioned respectively.

22. The manufacturing method as set forth in claim 21, comprising:
simultaneously forming a plurality of sacrificial growth portions around the device forming thin film.

23. The manufacturing method as set forth in claim 22, comprising:
forming the plurality of sacrificial growth portions so as to be point symmetric to each other, with respect to the device forming thin film.

24. The manufacturing method as set forth in claim 23, comprising:
forming the device forming thin film and the plurality of sacrificial growth portions each having the same shape, at constant intervals in two directions orthogonal to each other on the base wafer.

25. The manufacturing method as set forth in claim 21, comprising:
forming a semiconductor device on the device forming thin film, and
not forming, in the sacrificial growth portion, a semiconductor device capable of being used by a user using a finished semiconductor device product other than the semiconductor device formed on the device forming thin film.

26. The manufacturing method as set forth in claim 21, comprising:
scraping off the sacrificial growth portion after forming by the crystal growth.

27. The manufacturing method as set forth in claim 21, comprising:
covering the sacrificial growth portion with a protection film after forming by the crystal growth.

28. The manufacturing method as set forth in claim 21, wherein
the device forming thin film and the sacrificial growth portion include SiₓGe₁₋ₓ (0≦X<1) grown from the silicon of the base wafer exposed through the opening, the silicon serving as a growth nucleus, and a group III-V compound semiconductor grown from the SiₓGe₁₋ₓ serving as a growth nucleus, and
crystal growth of the group III-V compound semiconductor is carried out under a condition where supply of a precursor of the group III-V compound semiconductor is a rate-controlling factor.

29. The manufacturing method as set forth in claim 21, wherein
the device forming thin film and the sacrificial growth portion include SiₓGe₁₋ₓ (0≦X<1) grown from the silicon of the base wafer exposed through the opening, the silicon serving as a growth nucleus, and a group III-V compound semiconductor grown from the SiₓGe₁₋ₓ serving as a growth nucleus, and
crystal growth of the group III-V compound semiconductor is carried out under a condition where a reaction of a precursor of the group III-V compound semiconductor is a rate-controlling factor.

30. The manufacturing method as set forth in claim 21, wherein
the crystal growth is carried out by CVD.

31. A design method of a semiconductor device wafer, the semiconductor device wafer including: a device forming thin film for forming a semiconductor device; an inhibition portion for inhibiting growth of a precursor of the device forming thin film into a crystal; and a sacrificial growth portion that is formed by causing the precursor to sacrificially grow into a crystal, the design method comprising:
determining a size, a shape, and a position of the inhibition portion and a size, a shape, and a position of the sacrificial growth portion, based on a required specification of the device forming thin film.

32. The design method as set forth in claim 31, wherein
the semiconductor device wafer further includes a base wafer made of silicon, the inhibition portion includes an opening in which the device forming thin film is to be positioned and an opening in which the sacrificial growth portion is to be positioned, the openings exposing the base wafer, and the device forming thin film and the sacrificial growth portion are simultaneously formed, by crystal growth, in the opening in which the device forming thin film is to be positioned and in the opening in which the sacrificial growth portion is to be positioned respectively, the design method further comprising:
a step of designing a mask to be used for forming the opening in which the device forming thin film is to be positioned and the opening in which the sacrificial growth portion is to be positioned, based on the required specification of the device forming thin film; and the size, the shape, and the position of the inhibition portion, and the size, the shape, and the position of the sacrificial growth portion.

33. The design method as set forth in claim 31, wherein
the required specification of the device forming thin film includes at least one of the film thickness, a film composition, and a doping amount of the device forming thin film.
